(19) United States
(12) Patent Application Publication
(10) Pub. No.: US 2026/0032955 A1
(43) Pub. Date: Jan. 29, 2026

(54) TRANSISTOR WITH STACKED-UP SOURCE AND DRAIN CONTACTS AND METHODS OF FORMING THE SAME

(71) Applicant: Taiwan Semiconductor Manufacturing Company Limited, Hsinchu (TW)

(72) Inventors: Yun-Feng Kao, New Taipei City (TW); Ming-Yen Chuang, Hsinchu City (TW); Katherine H. Chiang, New Taipei City (TW); Kuo-Chang Chiang, Hsinchu (TW); Wu-Wei Tsai, Taoyuan City (TW); Yan-Yi Chen, Taipei City (TW)

(21) Appl. No.: 18/786,719

(22) Filed: Jul. 29, 2024

(51) Int. Cl. H01L 29/417; H01L 29/49; H01L 29/66; H01L 29/786

(52) U.S. Cl. CPC H10D 30/6729; H10D 30/031; H10D 30/6739; H10D 30/6757

(57) ABSTRACT

A transistor may include a gate, a gate dielectric layer on the gate, a channel layer on the gate dielectric layer and including a channel layer lower portion and a pair of channel layer upper portions on the channel layer lower portion, and a pair of source/drain contacts on the pair of channel layer upper portions, respectively. A method of forming a transistor may include forming a gate dielectric layer on a lower dielectric layer including a gate, depositing a layer of channel material on the gate dielectric layer, patterning the layer of channel material to form a channel layer including a channel layer lower portion and a pair of channel layer upper portions on the channel layer lower portion, forming an upper dielectric layer on the channel layer, and forming a pair of source/drain contacts in the upper dielectric layer on the pair of channel layer upper portions, respectively.

### BACKGROUND

A thin-film transistor (TFT) is a field-effect transistor (FET) that may be made by thin film deposition. The TFT may be grown on a supporting (but non-conducting) substrate, such as glass. This may differ from a bulk metal oxide field effect transistor (MOSFET), where the substrate may include a semiconductor material such as a silicon wafer.

There may be four common configurations of the TFT: a bottom contact/top gate configuration, a bottom contact/bottom gate configuration, a top contact/top gate configuration, and a top contact/bottom gate configuration. In each configuration, a semiconductor layer including a channel region may be formed adjacent a gate electrode (e.g., gate). The semiconductor layer may include, for example, amorphous silicon or polycrystalline silicon. The semiconductor layer may alternatively or additionally include cadmium selenide, metal oxides such as indium gallium zinc oxide (IGZO) or zinc oxide, organic semiconductors, carbon nanotubes, or metal halide perovskites.

In forming the TFT, the semiconductor layer may be deposited in a thin-film deposition process. A variety of techniques may be used to deposit the semiconductor layer, such as chemical vapor deposition (CVD), atomic layer deposition (ALD), and physical vapor deposition (PVD) (e.g., sputtering). The semiconductor layer can also be deposited from solution, via techniques such as printing or spray coating. The deposition process may be carried out under relatively low temperatures to avoid deforming the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of the transistor according to one or more embodiments.

FIG. 1B is a top-down view (plan view) of the transistor according to one or more embodiments.

FIG. 1C is a perspective view of the transistor according to one or more embodiments.

FIG. 2A is a vertical cross-sectional view of an intermediate structure including the lower dielectric layer according to one or more embodiments.

FIG. 2B is a vertical cross-sectional view of an intermediate structure including the gate in the lower dielectric layer according to one or more embodiments.

FIG. 2C is a vertical cross-sectional view of an intermediate structure including the gate dielectric layer on the gate and the lower dielectric layer according to one or more embodiments.

FIG. 2D is a vertical cross-sectional view of an intermediate structure including a layer of channel material on the gate dielectric layer according to one or more embodiments.

FIG. 2E is a vertical cross-sectional view of an intermediate structure including the channel layer according to one or more embodiments.

FIG. 2F is a vertical cross-sectional view of an intermediate structure including the upper dielectric layer according to one or more embodiments.

FIG. 2G is a vertical cross-sectional view of an intermediate structure including openings in the upper dielectric layer according to one or more embodiments.

FIG. 2H is a vertical cross-sectional view of an intermediate structure including a metal material layer on the upper dielectric layer according to one or more embodiments.

FIG. 3 is a flowchart illustrating a method of making the transistor according to one or more embodiments.

FIG. 4 is a top-down view (e.g., plan view) of a semiconductor device according to one or more embodiments.

FIG. 5 is a vertical cross-sectional view of a semiconductor device according to a first alternative embodiment.

FIG. 6 is a vertical cross-sectional view of a semiconductor device according to a second alternative embodiment.

FIG. 7A is a vertical cross-sectional view of an intermediate structure including the openings in the upper dielectric layer according to one or more embodiments.

FIG. 7B is a vertical cross-sectional view of an intermediate structure including channel material in the openings according to one or more embodiments.

FIG. 7C is a vertical cross-sectional view of an intermediate structure including a metal material layer on the channel material according to one or more embodiments.

FIG. 8 is a vertical cross-sectional view of a semiconductor device according to a third alternative embodiment.

FIG. 9 is a vertical cross-sectional view of a semiconductor device according to a fourth alternative embodiment.

FIG. 10A is a vertical cross-sectional view of an intermediate structure including the openings in the upper dielectric layer according to one or more embodiments.

FIG. 10B is a vertical cross-sectional view of an intermediate structure including the channel layer upper portions in the openings according to one or more embodiments.

FIG. 10C is a vertical cross-sectional view of an intermediate structure including a metal material layer in the openings according to one or more embodiments.

FIG. 11 is a vertical cross-sectional view of a semiconductor device according to a fifth alternative embodiment.

FIG. 12 is a vertical cross-sectional view of a semiconductor device according to a sixth alternative embodiment.

FIG. 13 is a vertical cross-sectional view of a semiconductor device according to a seventh alternative embodiment.

FIG. 14A is a vertical cross-sectional view of an intermediate structure including channel material in the openings according to one or more embodiments.

FIG. 14B is a vertical cross-sectional view of an intermediate structure including the channel layer upper portions according to one or more embodiments.

FIG. 14C is a vertical cross-sectional view of an intermediate structure including a metal material layer according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. The term “source/drain region” may refer to a source or a drain, individually or collectively depending upon the context. The term “active region” may also refer to the source or drain region.

In a bottom-gate transistor, the electric-field (e-field) may be enhanced under the S/D region due to the small space between the gate and source/drain (S/D) region (e.g., a short G-to-SD space). A high e-field may lead to a greater threshold voltage (Vt) shift during bias stress (positive bias stress (PBS) or negative bias stress (NBS). The high e-field may also lead to a poor time dependent dielectric breakdown (TDDB) behavior given the same operation bias. This detrimental high e-field effect is particularly impactful in thin-film-transistors (TFT), because of the smaller space between the gate and source/drain (S/D) region that is present in a TFT. Thus, TFTs of smaller sizes may suffer from greater threshold voltage shifts as well as poor time dependent breakdown behavior.

Various embodiments disclosed herein may include a provide approach for improving reliability of a transistors and in particular, TFTs. In particular, various embodiments disclosed herein may include different approaches to stack up the S/D contact in the TFT. The stacked-up S/D contact may help to improve reliability of the TFT. The stacked-up S/D contact may also be referred to as a multi-portioned S/D contact or a multi-portioned channel layer.

In at least one embodiment, the transistor may include a gate, a gate dielectric layer on the gate, a channel layer on the gate dielectric layer. The channel layer may include a channel layer lower portion and a pair of channel layer upper portions formed over the channel layer lower portion, and a pair of source/drain contacts formed over the pair of channel layer upper portions, respectively. The transistor (e.g., TFT) may be used, for example, in display technologies such as liquid crystal display (LCD), organic light-emitting diode (OLED) and low-temperature polycrystalline oxide (LTPO). The transistor may be used in memory applications, such as a selector serially connected with a passive device to construct a 1T1R RRAM/MRAM/PCM or 1T1C DRAM. The transistor may also improve a bias stability of a memory selector. The transistor (e.g., TFT) may also be utilized as a back end of line (BEOL) NMOS and integrated with front end of line (FEOL) PMOS to achieve CMOS logic functions.

In at least one embodiment, a method of forming the transistor may be provided. The method may include forming a lower dielectric layer (e.g., depositing an oxide material), and forming a gate (e.g., bottom gate) in the lower dielectric layer. The gate may be formed by forming an opening in the lower dielectric layer by a photolithographic process. The photolithographic process may include forming a patterned photoresist layer, and etching an opening in the lower dielectric layer through the patterned photoresist layer. A metal material may then be formed in the opening of the lower dielectric layer to form the gate. Chemical mechanical polishing (CMP) may then be used to planarize an upper surface of the gate and an upper surface of the lower dielectric layer. The gate dielectric layer (e.g., high-k gate dielectric layer) may then be formed over the lower dielectric layer including the gate. The channel layer may then be formed over the gate dielectric layer by depositing channel layer material (e.g., a layer of channel material) on the gate dielectric layer (e.g., depositing a thick layer of channel material for stacking up and patterning the channel material for stacking up a source/drain contact). The channel layer material may be patterned (e.g., using a photolithographic process) to form the channel layer including a channel layer lower portion and a pair of channel layer upper portions (e.g., low e-field region) on the channel layer lower portion. In some embodiment methods, the formation of the channel layer may occur over a plurality of steps. In some embodiments, the channel layer upper portion may include a material different than the material used to form the channel layer lower portion. Thus, multiple deposition and patterning steps may be used to form the channel layer. The channel layer lower portion and the channel layer upper portion may collectively form the stacked-up S/D contact.

An upper dielectric layer (e.g., interlayer dielectric layer; oxide material) may be deposited on the channel layer. A pair of openings may be formed (e.g., using a photolithographic process) in the upper dielectric layer over the pair of channel layer upper portions, respectively. A metal material may be formed in the pair of openings of the upper dielectric layer to form the pair of source/drain contacts. A CMP process may be performed to planarize an upper surface of the pair of source/drain contacts and an upper surface of the upper dielectric layer.

In the various embodiment transistors, the gate may have a thickness greater than 5 nm, although thicker or thinner gates may be used. The gate dielectric layer may have a thickness in a range of 2 nm to 15 nm, although thicker or thinner dielectric layers may be used. The channel layer lower portion may have a thickness in a range from 1 nm to 20 nm, although thicker or thinner channel layers may be used. The channel layer upper portions may have a thickness in a range from 1 nm to 20 nm. The source/drain contacts may have a thickness greater than 5 nm, although thicker or thinner source/drains may be used. The increase thickness of the channel layer (formed of the channel layer upper portion and channel layer lower portion) provides sufficient distance to mitigated against the detrimental enhanced e-field effects.

In the various embodiment transistors, a lower end of a source/drain contact (e.g., where the source/drain contact contacts a channel layer upper portion) may have a width in a first direction (e.g., the x-direction) greater than 5 nm. On both sides of the lower end of the source/drain contact, the channel layer upper portion may extend in the first direction more than 2 nm beyond the lower end of the source/drain contact. The channel layer upper portion may have a width greater than 9 nm and more than 4 nm greater than the width of the lower end of the source/drain contact. Thus, for example, in embodiments in which the width of the lower end of the source/drain contact is 10 nm, then the channel layer upper portion may be greater than 14 nm. The gate may extend in the first direction more than 2 nm beyond the pair of channel layer upper portions.

In the various embodiment transistors, each of the gate dielectric layer, the channel layer (including the channel layer lower portion and the pair of channel layer upper portions) and the pair of source/drain contacts may have a length in a second direction perpendicular to the first direction (e.g., in the y-direction) greater than 10 nm. In at least one embodiment, the gate dielectric layer, the channel layer and the pair of source/drain contacts may have substantially the same length in the second direction. In at least one embodiment, an edge of the gate dielectric layer, the channel layer and the pair of source/drain contacts may be substantially aligned in the second direction. The gate may have a length in the second direction greater than the length of each of the gate dielectric layer, the channel layer (including the channel layer lower portion and the pair of channel layer upper portions) and the pair of source/drain contacts. In at least one embodiment, the gate may extend in the second direction beyond the edge of the gate dielectric layer, channel layer and pair of source/drain contacts by at least 10 nm.

In at least one embodiment, the gate may include one or more of W, TiN, TaN, Cu, Pt, Mo, Al, Ru, Ti, Ta, or another metal with low resistivity (e.g., less than 1×10⁻⁵ ohm-cm). The gate dielectric may include a high-k dielectric material. In particular, the gate dielectric may include one or more of SiO₂, AlO₂, WOₓ, MoO₃, TiO₂, TaOₓ, Y₂O₃, HfO₂, HfAlO, BaHfO₃, BaTiO₂, and other material (e.g., oxide) having a dielectric constant greater than 3 (e.g., k>3). The channel layer (including the channel layer upper portions (low e-field regions)) may include one or more of InZnO (IZO), indium tin oxide (ITO), In₂O₃, Ga₂O₃, InGaZnO, ZnO, Al₂O₅Zn₂, aluminum doped ZnO (AZO), tungsten-doped indium oxide (IWO), TiOₓ. The channel layer may alternatively or additionally include semiconductor materials including other III-V materials, or combinations (e.g., alloys or stacked layers) of semiconductor materials. The source/drain contacts may include one or more of TiN, TaN, W, Cu, Pt, Mo, Ru, Al, Ti, Ta, or other metal with low resistivity (e.g., less than 1×10⁻⁵ ohm-cm).

In at least one embodiment, a bi-layer channel layer may be implemented. In particular, the channel layer upper portion may have a carrier concentration greater than a carrier concentration of the channel layer lower portion. This greater carrier concentration may allow the transistor to have a lower contact resistance between the channel layer and the source/drain contact. The higher carrier concentration in the channel layer upper portion may help to form an ohmic contact and have low contact resistance.

In embodiments that use the bi-layer channel, a low e-field region patterning mask (e.g., channel layer upper portion patterning mask) may be used. Alternatively, or additionally, the channel layer upper portion may be formed in an opening of an upper dielectric layer and the source/drain contact may be located in a recess in the channel layer upper portion. Thus, through re-deposition of the channel layer material (e.g., in the opening in the upper dielectric layer), the source/drain contact may still be stacked up but without the use of an extra low e-field region patterning mask.

In at least one embodiment, the channel layer may have a bi-layer structure including an intermediate layer on the channel layer lower portion. In this embodiment, the channel layer lower portion may include a high carrier concentration (e.g., high ON current) and the intermediate layer may have a lower carrier concentration (e.g., high threshold voltage (Vt)). The bi-layer structure may help to have both high Vt and driving current. By integrating the bi-layer structure with a re-deposition of the channel material (e.g., the channel layer upper portion is formed in an opening in the upper dielectric layer), the transistor may have a good threshold voltage/ON current (Vt/Ion) and negative bias stress (NBS) Vt stability at the same time.

In embodiments in which physical vapor deposition (PVD) is utilized to form the channel layer upper portion in an opening in the upper dielectric layer, the channel layer upper portion may not be conformally formed in the opening (e.g., inside the source/drain gap) but only grown at the bottom of the opening. This may allow more source/drain material (e.g., metal) to be filled into the opening which may further help to reduce contact resistance.

In at least one embodiment, the channel layer material (e.g., filling material) used to form the channel layer upper portion in an opening of the upper dielectric layer may be different than the channel layer material used to form the channel layer lower portion. In addition, multiple different channel layer materials may be used to form the channel layer upper portion in the opening of the upper dielectric layer. In this case, by using multiple different channel layer materials may help to obtain both high ON current and a reduction of the e-field.

In embodiments in which the channel layer material of the channel layer upper portion is formed in an opening in the upper dielectric layer, a thickness of a channel layer upper portion material may be reduced (thinned) by an etch back process. In such embodiments, a thickness of the channel layer material at a top side of the opening may be less than a thickness of the channel layer material at a bottom of the opening.

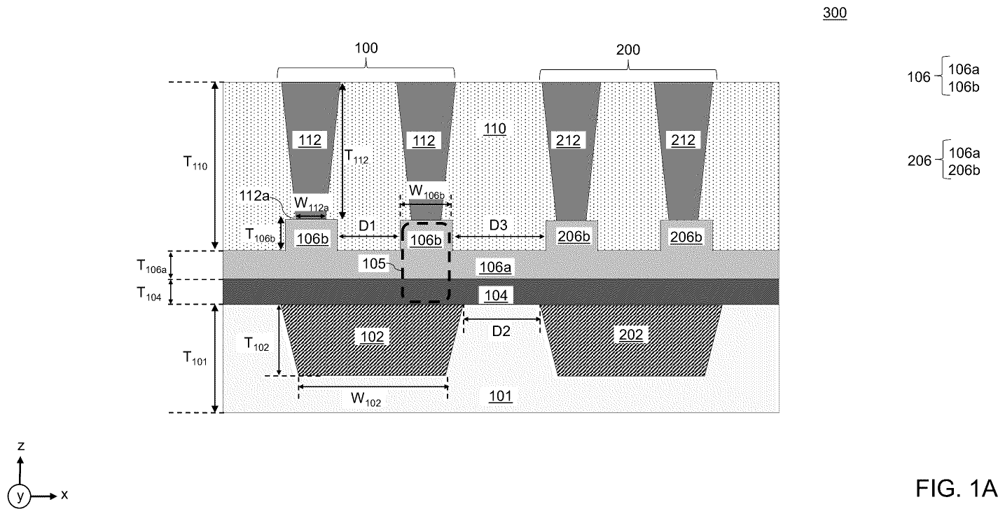

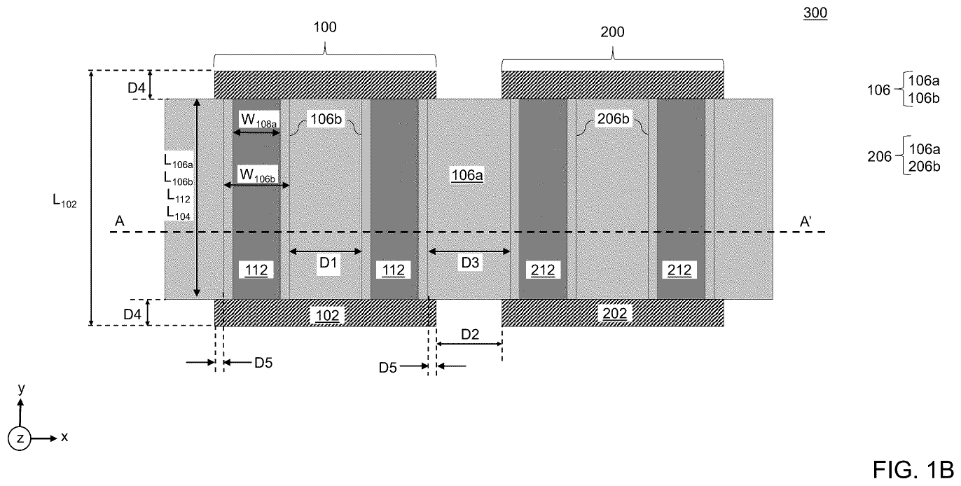

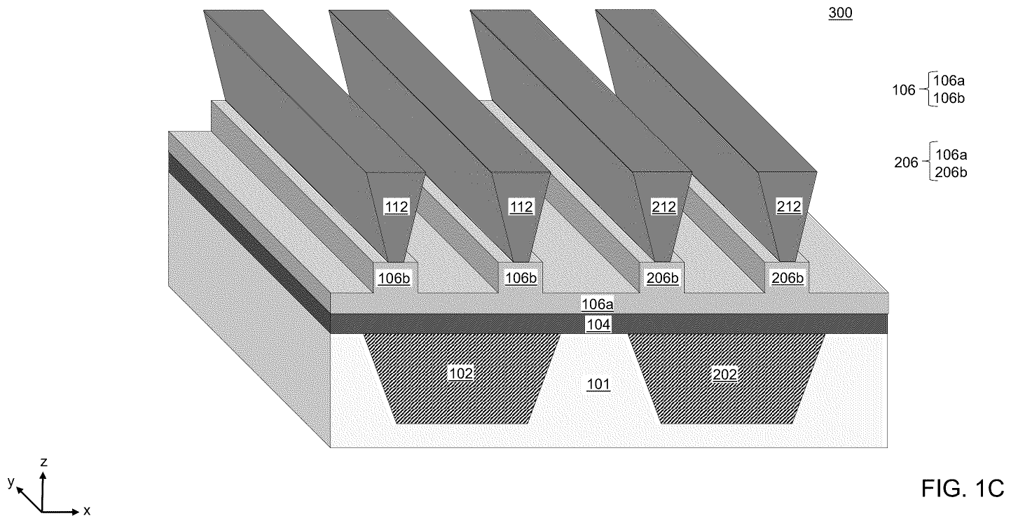

Referring to the drawings, FIGS. 1A-1C are various views of a semiconductor device 300 that may include a transistor 100 (e.g., a first transistor) and an adjacent transistor 200 (i.e., a second transistor) according to one or more embodiments. In particular, FIG. 1A is a vertical cross-sectional view of the transistor 100 and adjacent transistor 200 according to one or more embodiments. FIG. 1B is a top-down view (plan view) of the transistor 100 and adjacent transistor 200 according to one or more embodiments. The vertical cross-sectional view in FIG. 1A is the view along the line A-A′ in FIG. 1B. FIG. 1C is a perspective view of the transistor 100 and adjacent transistor 200 according to one or more embodiments.

As illustrated in FIG. 1A, the transistor 100 may include, for example, a gate 102, a gate dielectric layer 104 on the gate 102, and a channel layer 106 on the gate dielectric layer 104. The channel layer 106 may include a channel layer lower portion 106a and a pair of channel layer upper portions 106b on the channel layer lower portion 106a. The transistor 100 may also include a pair of source/drain contacts 112 on the pair of channel layer upper portions 106b of the channel layer 106, respectively. Thus, the source/drain contacts 112 may be referred to as stacked-up S/D contacts.

In this embodiment, the transistor 100 may space the source/drain contacts 112 away from the gate 102. As a result, a low e-field 105 may be produced in the channel layer 106 and the gate dielectric layer 104 between the gate 102 and the source/drain contacts 112. The low e-field 105 may help to avoid a large threshold voltage (Vt) shift during bias stress. The low e-field 105 may also help to improve the TDDB behavior of the transistor 100. The design may, therefore, help improve the reliability of the transistor 100.

The gate 102 of the transistor 100 may be located in a lower dielectric layer 101. The lower dielectric layer 101 may have a thickness T₁₀₁ greater than 8 nm. The lower dielectric layer 101 may include one or more dielectric material layers. In particular, the lower dielectric layer 101 may include any dielectric material known to be suitable for electrical isolation of the gate 102. In some embodiments, the lower dielectric layer 101 may include the elements of silicon, and at least one of oxygen and nitrogen. The lower dielectric layer 101 may include, for example, SiO, SiN, or SiON. The lower dielectric layer 101 may also be a low-K dielectric material (e.g., having a dielectric constant below that of SiO₂). Other materials for the lower dielectric layer 101 are within the contemplated scope of disclosure.

An upper surface of the gate 102 may be substantially co-planar with an upper surface of the lower dielectric layer 101. The gate 102 may have a thickness T₁₀₂ that is greater than 5 nm and a width W₁₀₂ in a first direction (in the x-direction) that is greater than 30 nm. The width W₁₀₂ of the gate 102 may be greater than the thickness T₁₀₂ of the gate 102. In at least one embodiment, the gate 102 may include one or more of W, TiN, TaN, Cu, Pt, Mo, Al, Ru, Ti, Ta, or another metal with low resistivity (e.g., less than 1×10⁻⁵ ohm-cm). Other materials for the gate 102 are within the contemplated scope of disclosure.

The gate 102 may have, for example, a square vertical cross-sectional shape, a rectangular vertical cross-sectional shape or a trapezoidal vertical cross-sectional shape. Other vertical cross-sectional shapes of the gate 102 are within the contemplated scope of disclosure.

The gate dielectric layer 104 may be formed on the upper surface of the gate 102 and the upper surface of the lower dielectric layer 101. The gate dielectric layer 104 may have a thickness T₁₀₄ that is in a range from about 2 nm to 15 nm. The gate dielectric layer 104 may include, for example, a high-k dielectric material. In at least one embodiment, the gate dielectric layer 104 may include one or more of SiO₂, AlO₂, WOₓ, MoO₃, TiO₂, TaOₓ, Y₂O₃, HfO₂, HfAlO, BaHfO₃, BaTiO₂, or other material (e.g., oxide) having a dielectric constant greater than 3 (e.g., k>3). Other materials for the gate dielectric layer 104 are within the contemplated scope of disclosure.

The channel layer 106 may be located on the gate dielectric layer 104 such that the gate dielectric layer 104 is between the channel layer 106 and the gate 102. In particular, the channel layer upper portions 106b of the channel layer 106 may be located on the channel layer lower portion 106a of the channel layer 106 over the gate 102. The low e-field 105 may be located in the channel layer upper portions 106b and extend downward into the channel layer lower portion 106a of the channel layer 106 and into the gate dielectric layer 104.

The channel layer lower portion 106a of the channel layer 106 may have a thickness T₁₀₆ₐ that is in a range from 1 nm to 20 nm. The channel layer upper portion 106b of the channel layer 106 may have a thickness T_{106b} that is in a range from about 1 nm to 20 nm. In at least one embodiment, the thickness T_{106b} of the channel layer upper portion 106b of the channel layer 106 may be greater than the thickness T₁₀₆ₐ of the channel layer lower portion 106a of the channel layer 106. The channel layer upper portion 106b of the channel layer 106 may also have a width W_{106b} that is greater than 9 nm. The width W_{106b} of each of the channel layer upper portions 106b (i.e., source and drain contacts) may be the same or different. The channel layer upper portions 106b of the channel layer 106 may be separated by a distance D1 in the first direction (the x-direction) in a range from 3 nm to 15 nm. The distance D1 between the channel layer upper portions 106b may be less than, greater than or equal to the width W_{106b} of each of the channel layer upper portions 106b.

The channel layer upper portion 106b of the channel layer 106 may have, for example, a square vertical cross-sectional shape, a rectangular vertical cross-sectional shape or a trapezoidal vertical cross-sectional shape. Other vertical cross-sectional shapes of the channel layer upper portion 106b are within the contemplated scope of disclosure.

The channel layer 106 including the channel layer lower portion 106a and the channel layer upper portions 106b may include one or more semiconductor materials. In at least one embodiment, the channel layer 106 may include one or more of IZO, ITO, In₂O₃, Ga₂O₃, InGaZnO, ZnO, Al₂O₅Zn₂, AZO, IWO, TiOₓ. The channel layer 106 may alternatively or additionally include semiconductor materials including other III-V materials, or combinations (e.g., alloys or stacked layers) of semiconductor materials. A material of the channel layer lower portion 106a of the channel layer 106 may be the same or different than a material of the channel layer upper portion 106b of the channel layer 106.

In an embodiment, a carrier concentration in channel layer lower portion 106a may be substantially the same as the carrier concentration in the channel layer upper portions 106b. In particular, the carrier concentration in the channel layer 106 (e.g., channel layer lower portion 106a and channel layer upper portions 106b) may be in a range from 5×10¹⁶ cm⁻³ to 1×10²⁰ cm⁻³. The carrier concentration in the channel layer lower portion 106a and channel layer upper portions 106b may be controlled, for example, by material selection (e.g., the carrier concentration of ITO is generally greater than the carrier concentration of IZO). The carrier concentration in the channel layer lower portion 106a and channel layer upper portions 106b may alternatively or additionally be controlled, for example, by doping techniques. Thus, for example in an embodiment, the channel layer upper portions 106b may be formed to have a higher carrier concentration than the channel layer lower portion 106a by using a first material (e.g., ITO) in the channel layer upper portions 106b and a second material (e.g., IZO) in the channel layer lower portion 106a. The channel layer upper portions 106b may alternatively or additionally be formed to have a higher carrier concentration than the channel layer lower portion 106a by adding a greater amount of dopant to the channel layer upper portions 106b than the amount of dopant added to the channel layer lower portion 106a.

An upper dielectric layer 110 may be formed on the channel layer 106. The channel layer upper portions 106b of the channel layer 106 may project upward from the channel layer lower portion 106a of the channel layer 106 into the upper dielectric layer 110. The upper dielectric layer 110 may contact a sidewall of the channel layer upper portions 106b of the channel layer 106. The upper dielectric layer 110 may also contact an upper surface of the channel layer lower portion 106a of the channel layer 106. The upper dielectric layer 110 may have a thickness Trio that is greater than 6 nm.

The upper dielectric layer 110 may include one or more dielectric material layers. The upper dielectric layer 110 may include a dielectric material that is substantially the same as the dielectric material of the lower dielectric layer 101. In particular, the upper dielectric layer 110 may include any dielectric material known to be suitable for electrical isolation of the gate 102. The upper dielectric layer 110 may include, for example, SiO, SiN, or SiON. The upper dielectric layer 110 may also be a low-K dielectric material (e.g., having a dielectric constant below that of SiO₂). Other materials for the upper dielectric layer 110 are within the contemplated scope of disclosure.

The source/drain contacts 112 may be formed in the upper dielectric layer 110. The source/drain contacts 112 may have a thickness T₁₁₂ that is greater than 5 nm. An upper surface of the source/drain contacts 112 may be substantially coplanar with an upper surface of the upper dielectric layer 110. A combined thickness T_{106b} of the channel layer upper portions 106b and the thickness T₁₁₂ of the source/drain contacts 112 may be substantially equal to the thickness T₁₁₀ of the upper dielectric layer 110.

In at least one embodiment, the pair of channel layer upper portions 106b may be in the upper dielectric layer 112, and the pair of source/drain contacts 112 is on an upper surface of the pair of channel layer upper portions 106b, respectively. In particular, the source/drain contacts 112 may include a lower end 112a where the source/drain contacts 112 contact the channel layer upper portion 106b, respectively. The lower end 112a of the source/drain contacts 112 may have a width W₁₁₂ₐ in a first direction (e.g., the x-direction) that is greater than 5 nm. On both sides of the lower end 112a of the source/drain contacts 112, the channel layer upper portions 106b may extend in the first direction more than 2 nm beyond the lower end 112a of the source/drain contacts 112. The width W_{106b} of the channel layer upper portions 106b may be greater than 9 nm and more than 4 nm greater than the width W₁₁₂ₐ of the lower end 112a of the source/drain contacts 112. Thus, for example, in embodiments in which the width W₁₁₂ₐ of the lower end 112a of the source/drain contacts 112 is 10 nm, then the width W_{106b} of the channel layer upper portions 106b may be greater than 14 nm.

The source/drain contacts 112 may have, for example, a square vertical cross-sectional shape, a rectangular vertical cross-sectional shape or a trapezoidal vertical cross-sectional shape. Other vertical cross-sectional shapes of the source/drain contacts 112 are within the contemplated scope of disclosure. The source/drain contacts may include one or more of TiN, TaN, W, Cu, Pt, Mo, Ru, Al, Ti, Ta, or other metal with low resistivity (e.g., less than 1×10⁻⁵ ohm-cm). Other materials for the source/drain contacts 112 are within the contemplated scope of disclosure.

As further illustrated in FIG. 1A, an adjacent transistor 200 (e.g., second transistor) may be formed adjacent to the transistor 100 in the first direction. The transistor 100 and adjacent transistor 200 may together constitute a semiconductor device 300. The semiconductor device 300 may be included, for example, in display technologies such as LCD, OLED, etc. The semiconductor device 300 may be included in other device technologies as well.

The adjacent transistor 200 may include a gate 202 (e.g., second gate) in the lower dielectric layer 101. An upper end of the gate 202 may be separated in the first direction from an upper end of the gate 102 in transistor 100 by a distance D2 that may be greater than 10 nm. The gate dielectric layer 104 and the channel layer lower portion 106a may be located on the gate 202 and may also be included as part of the adjacent transistor 200. Thus, the gate dielectric layer 104 and the channel layer lower portion 106a may be part of both the transistor 100 and the adjacent transistor 200.

The adjacent transistor 200 may also include a pair of channel layer upper portions 206b (e.g., second pair of channel layer upper portions) on the channel layer lower portion 106a. That is, the adjacent transistor 200 may include a channel layer 206 including the channel layer lower portion 106a and the channel layer upper portions 206b. In at least one embodiment, a carrier concentration in the channel layer upper portions 206b may be substantially the same as the carrier concentration in the channel layer lower portion 106a and the channel layer upper portions 106b. In particular, the carrier concentration in the channel layer 106 may be in the range from 5×10¹⁶ cm⁻³ to 1×10²⁰ cm⁻³.

The channel layer upper portions 206b in the adjacent transistor 200 may be separated in the first direction from the channel layer upper portions 106b in transistor 100 by a distance D3 that may be greater than 14 nm. The adjacent transistor 200 may also include a pair of source/drain contacts 212 (e.g., second pair of source/drain contacts) on the pair of channel layer upper portions 206b, respectively. The features of the gate 202, channel layer upper portions 206b and source/drain contacts 212 may be substantially the same as the features of the gate 102, channel layer upper portions 106b and source/drain contacts 112 as described above with respect to transistor 100.

Referring again to FIGS. 1B and 1C, the lower dielectric layer 101 and upper dielectric layer 110 are omitted from FIGS. 1B and 1C for ease of understanding. As illustrated in FIG. 1B, the gate 102 may have a length L₁₀₂ that may be greater than 20 nm in a second direction (y-direction) perpendicular to the first direction. The gate 102 may extend in the second direction beyond opposing sidewalls of the channel layer lower portion 106a by a distance D4 that may be greater than 5 nm. The gate 102 may also extend in the first direction beyond the channel layer upper portions 106b by a distance D5 that mat be greater than 2 nm.

The opposing sidewalls in the second direction of the channel layer lower portion 106a, channel layer upper portions 106b, source/drain contacts 112 and gate dielectric layer 104 (not shown) may be substantially aligned. A length L₁₀₆ₐ of the channel layer lower portion 106a, a length L_{106b} of the channel layer upper portions 106b, a length L₁₁₂ of the source/drain contacts 112, and a length L₁₀₄ of the gate dielectric layer 104 (not shown) may all be substantially the same. Each of the length L₁₀₆ₐ of the channel layer lower portion 106a, the length L_{106b} of the channel layer upper portions 106b, the length L₁₁₂ of the source/drain contacts 112, and the length L₁₀₄ of the gate dielectric layer 104 may be greater than 10 nm. Again, the features of the gate 202, channel layer upper portions 206b and source/drain contacts 212 may be substantially the same as the features of the gate 102, channel layer upper portions 106b and source/drain contacts 112 as described above with respect to transistor 100.

Referring again to FIG. 1C, the upper dielectric layer 110 is omitted from FIG. 1C for ease of understanding. As illustrated in FIG. 1C, the channel layer upper portions 106b may have a bar-shape extending lengthwise in the second direction (y-direction). The source/drain contacts 112 may be tapered in a third direction (z-direction) toward the gate 102. In particular, the source/drain contacts 112 may have a truncated wedge shape projecting from the channel layer upper portions 106b in the third direction (z-direction) and extending lengthwise in the second direction. The shapes and sizes of the channel layer upper portions 106b, although shown as uniform in FIG. 1C, may vary. The shapes and sizes of the source/drain contacts 112, although shown as uniform in FIG. 1C, may also vary.

In FIGS. 1A-1C, the transistor 100 and adjacent transistor 200 are illustrated as having the same characteristics in terms of types of transistors (e.g., p-type or n-type), materials used for each of the components (e.g., material for gate, channel layer upper portions and channel layer lower portions), and dimensions (e.g., thickness of channel layer upper portions, thickness of contacts, etc.). Embodiments are contemplated in which these various characteristics may be the same or different between the transistor 100 and adjacent transistor 200. For sake of simplicity, the illustration and description of the various combinations of differences and processes to form the varying combinations are omitted. However, these varying combinations and processes to form the transistor 100 and adjacent transistor 200 of varying characteristics are within the contemplated scope of disclosure.

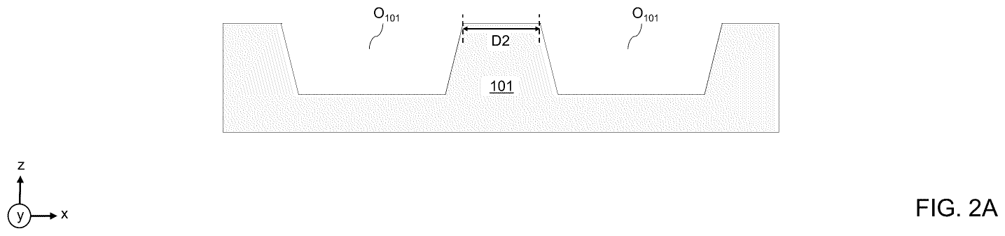

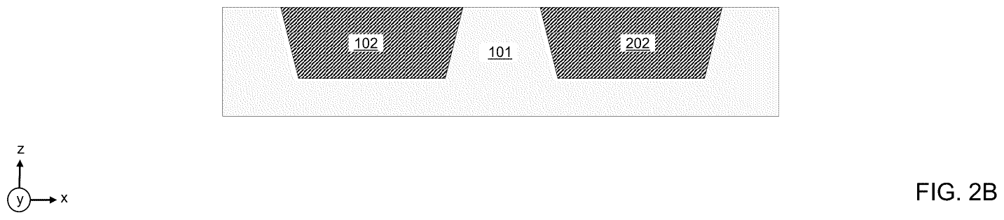

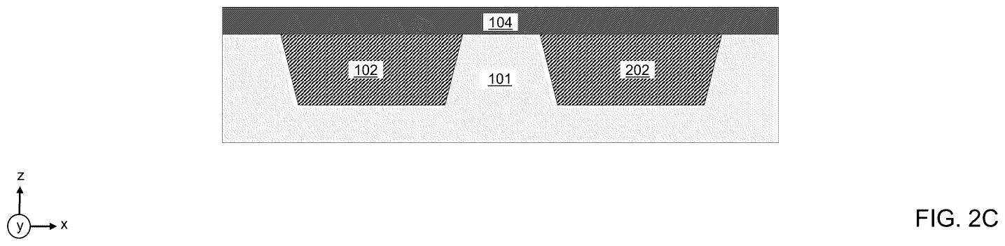

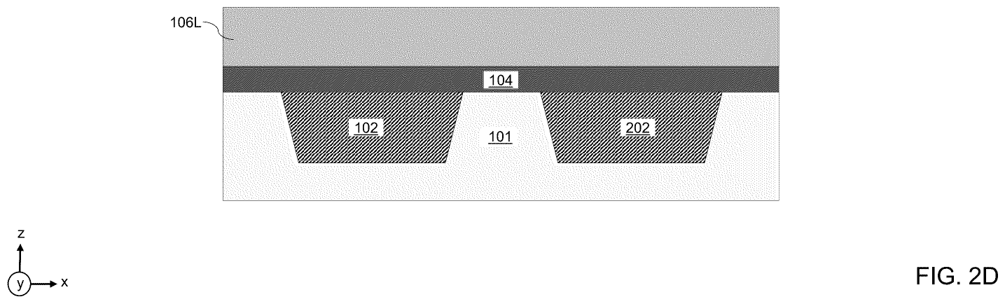

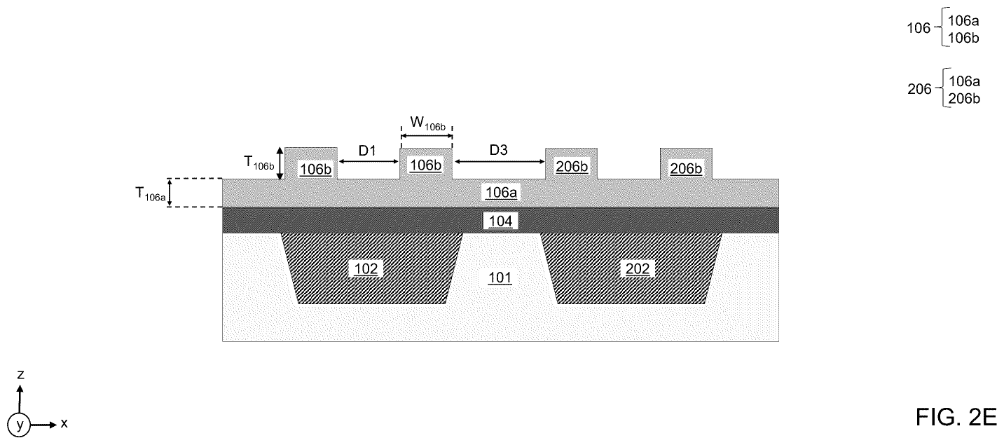

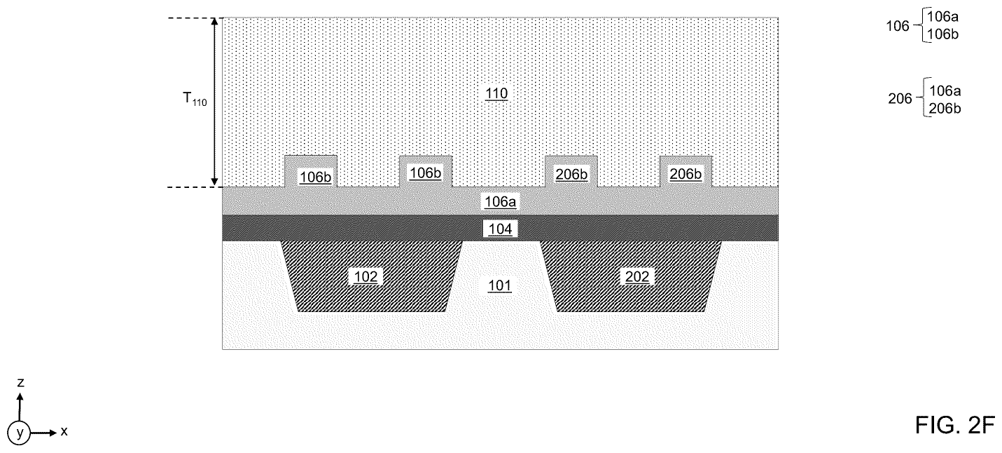

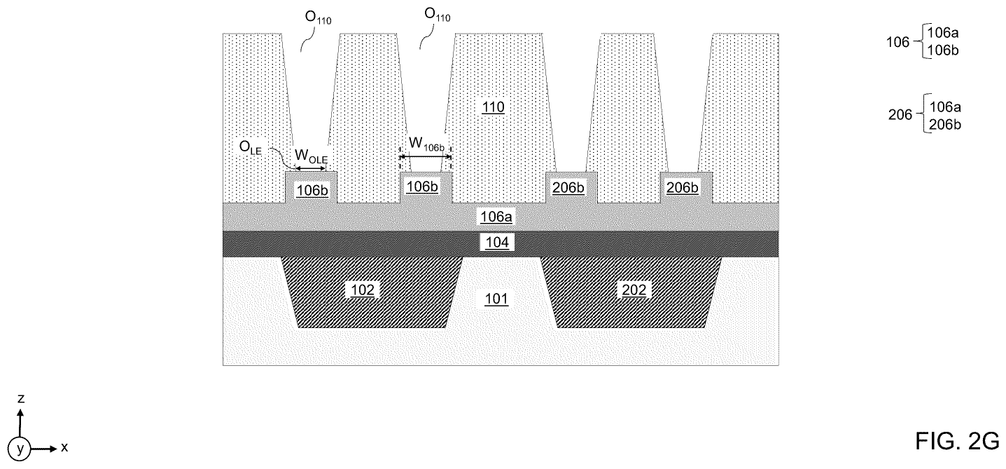

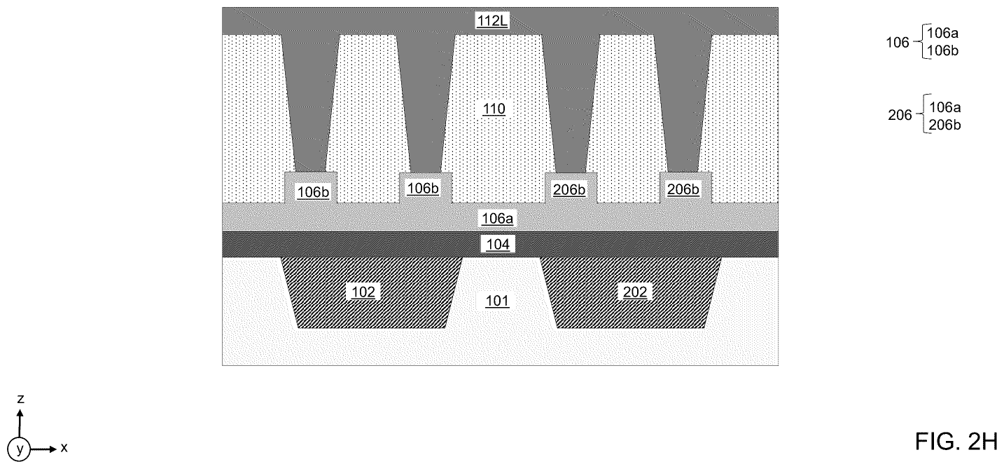

FIGS. 2A-2H are vertical cross-sectional views of various intermediate structures in a method of forming the transistor 100. It should be noted that the adjacent transistor 200 may be formed concurrently with the forming of the transistor 100 using substantially the same processes as those used to form the transistor 100.

In particular, FIG. 2A is a vertical cross-sectional view of an intermediate structure including the lower dielectric layer 101 according to one or more embodiments. The lower dielectric layer 101 may be formed on a substrate (not shown) (e.g., carrier substrate). The lower dielectric layer 101 may be formed, for example, by depositing a layer of dielectric material (e.g., SiO₂) on the substrate. The layer of dielectric material may be deposited by chemical vapor deposition (CVD), physical vapor deposition (PVD) (e.g., sputtering), atomic layer deposition (ALD), plasma-enhanced CVD (PECVD), low-pressure chemical vapor deposition (LPCVD), or other suitable deposition method. In at least one embodiment, the layer of dielectric material may include a layer of SiO₂ deposited by using tetraethosiloxane (TEOS) as the reactant gas. In at least one embodiment, the layer of dielectric material may be deposited to a thickness greater than 10 nm.

A photolithographic process may then be performed to pattern the layer of dielectric material and form openings O₁₀₁ in the dielectric material. The photolithographic process may include forming a patterned photoresist mask (not shown) on the layer of dielectric material, and etching (e.g., wet etching, dry etching, etc.) the layer of dielectric material through openings in the photoresist mask to form the openings O₁₀₁. The openings O₁₀₁ may be formed to have a depth greater than 5 nm and separated by the distance D2 that may be greater than 10 nm. The photoresist mask may be subsequently removed by ashing, dissolving the photoresist mask or by consuming the photoresist mask during the etch process.

FIG. 2B is a vertical cross-sectional view of an intermediate structure including the gate 102 in the lower dielectric layer 101 according to one or more embodiments. After the openings O₁₀₁ are formed in the layer of dielectric material, a metal material may be deposited on the dielectric material and in the openings O₁₀₁. The metal material may include, for example, W, TiN, TaN, Cu, Pt, Mo, Al, Ru, Ti, Ta, or another metal with low resistivity (e.g., less than 1×10⁻⁵ ohm-cm). The metal material may fill the openings O₁₀₁ and be formed on an upper surface of the dielectric material. The metal material may be deposited on the dielectric material, for example, by CVD, PVD (e.g., sputtering), ALD, PECVD, LPCVD, or other suitable deposition method. The metal material may then be planarized such as by CMP in order to make an upper surface of the gate 102 substantially coplanar with an upper surface of the lower dielectric layer 101.

FIG. 2C is a vertical cross-sectional view of an intermediate structure including the gate dielectric layer 104 on the gate 102 and the lower dielectric layer 101 according to one or more embodiments. As illustrated in FIG. 2C, the gate dielectric layer 104 may be formed on the upper surface of the gate 102 and the upper surface of the lower dielectric layer 101. The gate dielectric layer 104 may be formed to have a thickness T₁₀₄ that may be in a range from 2 nm to 15 nm.

In at least one embodiment, the gate dielectric layer 104 may be formed by depositing a dielectric material (e.g., high-k dielectric material) on the gate dielectric layer 104 and gate 102. In at least one embodiment, the dielectric material may include one or more of SiO₂, AlO₂, WOₓ, MoO₃, TiO₂, TaOₓ, Y₂O₃, HfO₂, HfAlO, BaHfO₃, BaTiO₂, or other material (e.g., oxide) having a dielectric constant greater than 3 (e.g., k>3). The dielectric material may be deposited on the lower dielectric layer 101 and gate 102, for example, by CVD, PVD (e.g., sputtering), ALD, PECVD, LPCVD, or other suitable deposition method, to form the gate dielectric layer 104. An upper surface of the gate dielectric layer 104 may then be polished by performing, for example, CMP using an appropriate polishing slurry.

FIG. 2D is a vertical cross-sectional view of an intermediate structure including a layer of channel material 106L on the gate dielectric layer 104 according to one or more embodiments. The layer of channel material 106L may include, for example, one or more of IZO, ITO, In₂O₃, Ga₂O₃, InGaZnO, ZnO, Al₂O₅Zn₂, AZO, IWO, TiOₓ. The layer of channel material 106L may alternatively or additionally include semiconductor materials including other III-V materials, or combinations (e.g., alloys or stacked layers) of semiconductor materials.

In at least one embodiment, the layer of channel material 106L may be formed to have a thickness that may be in a range from 2 nm to 40 nm, although thicker or thinner thicknesses may be used. The layer of channel material 106L may be deposited on the gate dielectric layer 104, for example, by CVD, PVD (e.g., sputtering), ALD, PECVD, LPCVD, or other suitable deposition method.

After the layer of channel material 106L is deposited, the layer of channel material 106L may be doped in order to adjust a carrier concentration of the layer of channel material 106L. An upper surface of the layer of channel material 106L may also be planarized (e.g., polished) to adjust a thickness of the layer of channel material 106L. The upper surface of the layer of channel material 106L may be planarized by performing, for example, CMP using an appropriate polishing slurry.

FIG. 2E is a vertical cross-sectional view of an intermediate structure including the channel layer 106 according to one or more embodiments. As illustrated in FIG. 2E, the channel material 106L may be patterned to form the channel layer 106. In particular, the channel material 106L may be patterned to form the channel layer lower portion 106a and the channel layer upper portions 106b on the channel layer lower portion 106a.

The channel material 106L may be patterned, for example, by performing a photolithographic process on the channel material 106L. The photolithographic process may include forming a patterned photoresist mask (not shown) on the channel material 106L, and etching (e.g., wet etching, dry etching, etc.) the channel material 106L through openings in the photoresist mask to form.

The patterning of the channel material 106L may be performed so that the channel layer lower portion 106a may have a thickness T₁₀₆ₐ that may be in a range from 1 nm to 20 nm. The patterning may also be performed so that the channel layer upper portions 106b has a thickness T_{106b} that may be in a range from 1 nm to 20 nm and a width W_{106b} that may be greater than 9 nm. The patterning may also be performed so that the channel layer upper portions 106b (and similarly channel layer upper portions 206b) may be separated by a distance D1 in a range from 3 nm to 15 nm. The patterning may also be performed so that the channel layer upper portions 206b in the adjacent transistor 200 may be separated from the channel layer upper portions 106b in transistor 100 by a distance D3 that may be greater than 14 nm. The photoresist mask may be subsequently removed by ashing, dissolving the photoresist mask or by consuming the photoresist mask during the etch process. While FIGS. 2E-2H illustrate the channel layer upper portions 206b of the adjacent transistor 200 to have the same dimensions as the channel layer upper portions 106b of the transistor 100 for sake of simplicity, embodiments in which the channel material 106L is patterned to form channel layer upper portions 206b and channel layer upper portions 106b of varying dimensions are within the contemplated scope of disclosure.

FIG. 2F is a vertical cross-sectional view of an intermediate structure including the upper dielectric layer 110 according to one or more embodiments. As illustrated in FIG. 2F, the upper dielectric layer 110 may be formed on the channel layer 106 including the channel layer lower portion 106a and the channel layer upper portions 106b (and/or channel layer lower portion 106a and the channel layer upper portions 206b). The upper dielectric layer 110 may be formed such that a space between the channel layer upper portions 106b and the channel layer upper portions 206b of the adjacent transistor 200 may be filled with the upper dielectric layer 110.

The upper dielectric layer 110 may be formed by a process similar to the process of forming the lower dielectric layer 101. In particular, the upper dielectric layer 110 may be formed by depositing a layer of dielectric material (e.g., SiO₂) on the channel layer 106. The layer of dielectric material may be deposited by chemical vapor deposition (CVD), physical vapor deposition (PVD) (e.g., sputtering), atomic layer deposition (ALD), plasma-enhanced CVD (PECVD), low-pressure chemical vapor deposition (LPCVD), or other suitable deposition method. In at least one embodiment, the layer of dielectric material may include a layer of SiO₂ deposited by using tetraethosiloxane (TEOS) as the reactant gas. In at least one embodiment, the layer of dielectric material may be deposited to a thickness Tio greater than 6 nm. An upper surface of the layer of dielectric material may then be polished by performing, for example, CMP using an appropriate polishing slurry to form the upper dielectric layer 110.

FIG. 2G is a vertical cross-sectional view of an intermediate structure including openings O₁₁₀ in the upper dielectric layer 110 according to one or more embodiments. As illustrated in FIG. 2G, after the upper dielectric layer 110 is formed (see FIG. 2F), a photolithographic process may be performed to pattern the upper dielectric layer 110 to include openings O₁₁₀. The photolithographic process may include forming a patterned photoresist mask (not shown) on the upper dielectric layer 110, and etching (e.g., wet etching, dry etching, etc.) the upper dielectric layer 110 through openings in the photoresist mask to form the openings O₁₁₀.

The openings O₁₁₀ may be formed so as to be centered (e.g., in the first direction) on the channel layer upper portions 106b, 206b, respectively. The openings O₁₁₀ may be formed so as to have a depth greater than 5 nm. The openings O₁₁₀ may be formed so as to expose an upper surface of the channel layer upper portions 106b. 206b. The openings O₁₁₀ may also be formed to have an opening lower end OLE having a width WOLE in the first direction greater than 5 nm. The openings O₁₁₀ may also be formed so that width WOLE of the opening lower end OLE is less than the width W_{106b} of the channel layer upper portions 106b. The openings O₁₁₀ may be formed to have a substantially vertical cross-sectional trapezoidal shape. Other vertical cross-sectional shapes and sizes of the openings O₁₁₀ are within the contemplated scope of disclosure. The photoresist mask may be subsequently removed by ashing, dissolving the photoresist mask or by consuming the photoresist mask during the etch process.

FIG. 2H is a vertical cross-sectional view of an intermediate structure including a metal material layer 112L on the upper dielectric layer 110 according to one or more embodiments. After the openings O₁₁₀ are formed in the layer of dielectric material (see FIG. 2G), a metal material layer 112L may be formed on the layer of dielectric material and in the openings O₁₁₀. The metal material layer 112L may include, for example, one or more of TIN, TaN, W, Cu, Pt, Mo, Ru, Al, Ti, Ta, or other metal with low resistivity (e.g., less than 1×10⁻⁵ ohm-cm). Other materials for the metal material layer 112L are within the contemplated scope of disclosure.

The metal material layer 112L may fill the openings O₁₁₀ and be formed on an upper surface of the upper dielectric layer 110. The metal material layer 112L may be deposited on the upper dielectric layer 110, for example, by CVD, PVD (e.g., sputtering), ALD, PECVD, LPCVD, or other suitable deposition method. The metal material layer 112L may then be planarized such as by CMP in order to form the source/drain contacts 112 (see FIG. 1A) in the openings O₁₁₀ and to make an upper surface of the source/source contacts 112 substantially coplanar with an upper surface of the upper dielectric layer 110.

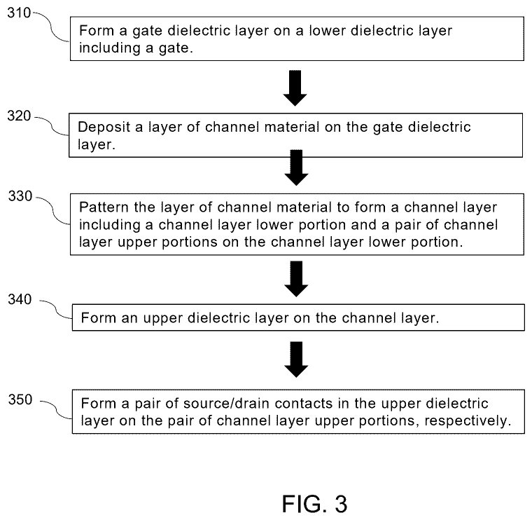

FIG. 3 is a flowchart illustrating a method of making the transistor 100 according to one or more embodiments. Step 310 of the method may include forming a gate dielectric layer on a lower dielectric layer including a gate. Step 320 of the method may include depositing a layer of channel material on the gate dielectric layer. Step 330 of the method may include patterning the layer of channel material to form a channel layer including a channel layer lower portion and a pair of channel layer upper portions on the channel layer lower portion. Step 340 of the method may include forming an upper dielectric layer on the channel layer. Step 350 of the method may include forming a pair of source/drain contacts in the upper dielectric layer on the pair of channel layer upper portions, respectively.

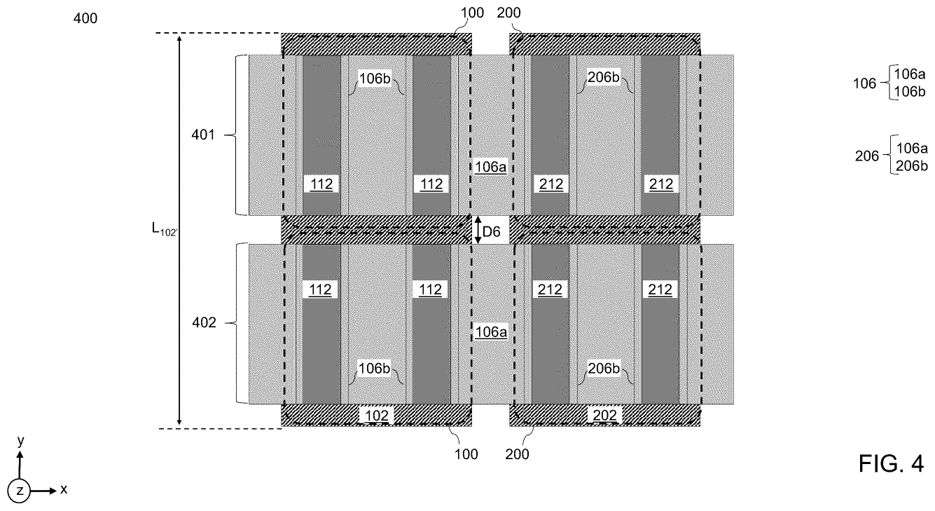

FIG. 4 is a top-down view (e.g., plan view) of a semiconductor device 400 according to one or more embodiments. As illustrated in FIG. 4, the semiconductor device 400 may include a transistor first set 401 and a transistor second set 402. The transistor first set 401 may include the transistor 100 and the adjacent transistor 200. The transistor second set 402 may also include the transistor 100 and the adjacent transistor 200. In each of the transistor first set 401 and the transistor second set 402, the transistor 100 and the adjacent transistor share the gate dielectric layer 104 and the channel layer lower portion 106a (see e.g., FIGS. 1A and 1C). The channel layer lower portion 106a (and the underlying gate dielectric layer 104) in the transistor first set 401 may extend substantially parallel to the channel layer lower portion 106a (and the underlying gate dielectric layer 104) in the transistor second set 402. The transistor first set 401 may be separated from the transistor second set 402 in the second direction by a distance D6 that may be greater than 5 nm. In particular, the channel layer lower portion 106a in the transistor first set 401 may be separated in the second direction from the channel layer lower portion 106a in the transistor second set 402 by the distance D6 greater than 5 nm. The gate dielectric layer 104 in the transistor first set 401 may also be separated in the second direction from the dielectric layer 104 in the transistor second set 402 by the distance D6 that may be greater than 5 nm.

The transistor first set 401 and the transistor second set 402 may share the gate 102 and the gate 202. In particular, the transistor 100 in both the transistor first set 401 and the transistor second set 402 include the gate 102. The gate 102 may have a length L₁₀₂ in the second direction (y-direction) greater than the length L₁₀₂ of the gate 102 described above with respect to FIG. 1B. In particular, the length L₁₀₂ of the gate 102 in the semiconductor device 400 may be greater than 40 nm. The length of the second gate 202 in the second direction may be substantially the same as the length L₁₀₂. of the gate 102 in the semiconductor device 400 (e.g., greater than 40 nm).

It should be noted that although the semiconductor device 400 is shown having only the first transistor set 401 and the second transistor set 402, the semiconductor device 400 may include any number of transistor sets, each of which may be separated in the second direction by a distance D6 that may be greater than 5 nm. It should also be noted that although the first transistor set 401 and second transistor set 402 are shown including only the transistor 100 and adjacent transistor 200, both the first transistor set 401 and second transistor set 402 may include any number of transistors formed along the first direction (x-direction).

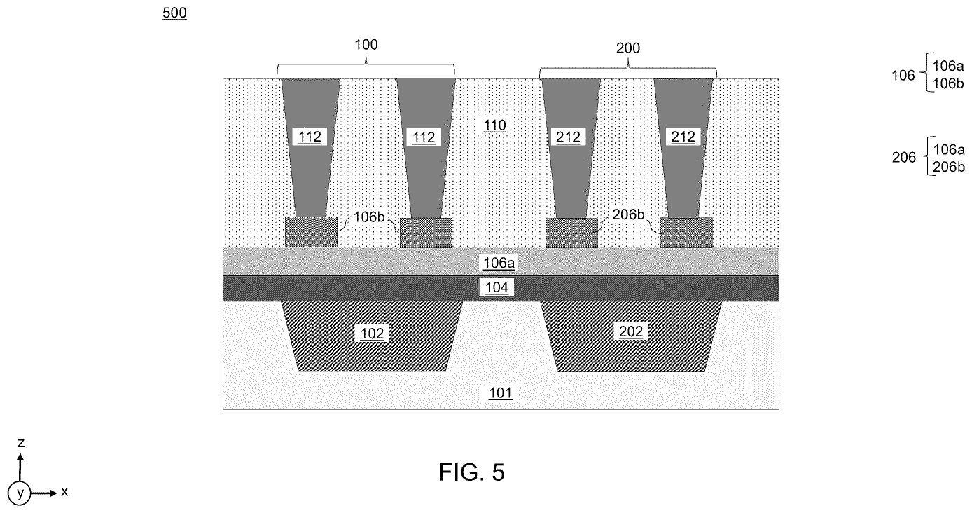

FIG. 5 is a vertical cross-sectional view of a semiconductor device 500 according to a first alternative embodiment. The semiconductor device 500 may include a transistor 100 (e.g., a first transistor) and/or an adjacent transistor 200 (i.e., a second transistor) having a first alternative configuration. As illustrated in FIG. 5, the first alternative configuration of the transistor 100 and the adjacent transistor 200 in the semiconductor device 500 may be substantially the same as the configuration of the transistor 100 and adjacent transistor 200 in FIG. 1A-1C. In particular, each of the channel layer lower portion 106a and the channel layer upper portions 106b, 206b may include one or more of IZO, ITO, In₂O₃, Ga₂O₃, InGaZnO, ZnO, Al₂O₅Zn₂, AZO, IWO, TiOₓ. Each of the channel layer lower portion 106a and the channel layer upper portions 106b, 206b may alternatively or additionally include semiconductor materials including other III-V materials, or combinations (e.g., alloys or stacked layers) of semiconductor materials.

However, as illustrated in FIG. 5, in the first alternative configuration of the transistor 100 and/or the adjacent transistor 200, the channel layer upper portions 106b, 206b may be different in some respect from the channel layer lower portion 106a. In particular, a carrier concentration in the channel layer upper portions 106b, 206b may be different than a carrier concentration in the channel layer lower portion 106a. Due to the channel layer upper portions 106b, 206b and the channel layer lower portion 106a having different carrier concentrations, the channel layer upper portions 106b, 206b may have one or more properties different than the respective properties of the channel layer lower portion 106a. A material of the channel layer upper portions 106b, 206b may be the same or different than a material of the channel layer lower portion 106a. In some embodiments, the material of the channel layer upper portion 106b and channel layer upper portion 206b may be the same or different as each other. In some embodiments, the material of either the channel layer upper portions 106b, 206b may be the same as the material of the channel layer lower portion 106a, while the material of the other of channel layer upper portions 106b, 206b may be different.

Thus, in the first alternative configuration in FIG. 5, the channel layer 106 may be formed as a bi-layer channel layer. In particular, the channel layer lower portion 106a may constitute a first layer of the bi-layer and the channel layer upper portions 106b and/or 206b may constitute a second layer of the bi-layer. The channel layer 106 may be formed, for example, in three steps. First, the channel layer lower portion 106a may be formed by depositing a first layer of channel material (e.g., having a first carrier concentration) on the gate dielectric layer 104. The channel layer upper portions 106b (and/or 206b) may then be formed by depositing a second layer of channel material (e.g., having a second carrier concentration greater than the first carrier concentration) on the first layer of channel material. The second layer of channel material may then be patterned (e.g., using a photolithographic process) to form the pair of channel layer upper portions 106b (and/or 206b).

In at least one embodiment, the channel layer upper portions 106b (and/or 206b) may have a carrier concentration greater than a carrier concentration of the channel layer lower portion 106a. In at least one embodiment, the channel layer upper portions 106b (and/or 206b) may have a high carrier concentration and the channel layer lower portion 106a may have a low carrier concentration. In at least one embodiment, the channel layer upper portions 106b (and/or 206b) may have a carrier concentration in a range from about 1×10¹⁸ cm⁻³ to 1×10²⁰ cm⁻³, and the channel layer lower portion 106a may have a carrier concentration in a range from about 5×10¹⁶ cm⁻³ to 1×10¹⁸ cm⁻³.

By including the channel layer upper portions 106b (and/or 206b) with a carrier concentration greater than a carrier concentration of the channel layer lower portion 106a, the first alternative configuration in FIG. 5 may allow the transistor 100 and/or the adjacent transistor 200 to have a lower contact resistance between the channel layer upper portions 106b (and/or 206b) and the source/drain contacts 112. The higher carrier concentration in the channel layer upper portions 106b (and/or 206b) may help to form an ohmic contact and have low contact resistance.

It should be noted that the adjacent transistor 200 in the first alternative configuration may have the same features as the features described above for the transistor 100. In particular, the channel layer upper portions 206b may have a carrier concentration greater than a carrier concentration of the channel layer lower portion 106a. The channel layer upper portions 206b in the adjacent transistor 200 may alternatively include a material different than the material the channel layer upper adjacent transistor 200 may alternatively include a carrier concentration different than a carrier concentration of the channel layer upper portions 106b in the transistor 100.

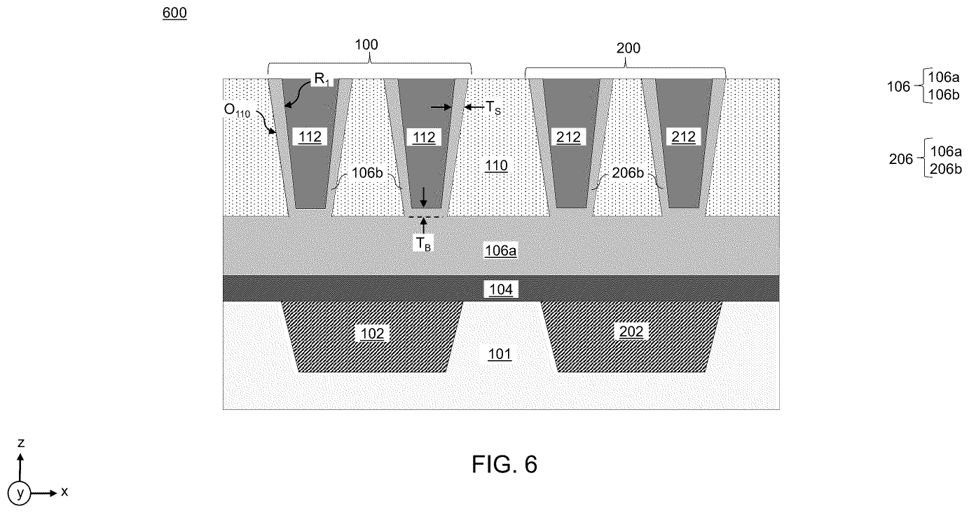

FIG. 6 is a vertical cross-sectional view of a semiconductor device 600 according to a second alternative embodiment. The semiconductor device 600 may include a transistor 100 (e.g., a first transistor) and/or an adjacent transistor 200 (i.e., a second transistor) having a second alternative configuration. It should be noted that the adjacent transistor 200 in the second alternative configuration may have the same features as the features described for the transistor 100. In some embodiments, the features of the adjacent transistor 200 in the second alternative configuration may be different than the features described for the transistor 100.

As illustrated in FIG. 6, the transistor 100 having the second alternative configuration may be substantially similar to the configuration in FIGS. 1A-1C. However, in the transistor 100 having the second configuration, the channel layer upper portions 106b may be formed in an opening O₁₁₀ of an upper dielectric layer 110. Further, the source/drain contacts 112 may be located in recesses R₁ in the channel layer upper portions 106b. In at least one embodiment, a source/drain contact 112 of the pair of source/drain contacts 112 may be tapered in a direction toward the gate 102 and a channel layer upper portion 106b of the pair of channel layer upper portions 106b may be on a sidewall of the source/drain contact 112. Thus, through re-deposition of the channel layer material (e.g., in the opening in the upper dielectric layer 110), the source/drain contacts 112 may be stacked up above the channel layer lower portion 106a.

The channel layer lower portion 106a and the channel layer upper portions 106b may include, for example, one or more of IZO, ITO, In₂O₃, Ga₂O₃, InGaZnO, ZnO, Al₂O₅Zn₂, AZO, IWO, TiOₓ. The channel layer lower portion 106a and the channel layer upper portions 106b may alternatively or additionally include semiconductor materials including other III-V materials, or combinations (e.g., alloys or stacked layers) of semiconductor materials.

As illustrated in FIG. 6, the channel layer upper portions 106b may have a sidewall thickness Ts greater than 0.5 nm on a sidewall of the openings in the upper dielectric layer 110. The channel layer upper portions 106b may also have a bottom thickness TB greater than 0.5 nm on a bottom of the openings in the upper dielectric layer 110. In at least one embodiment, a thickness of the channel layer upper portions 106b may be substantially uniform throughout an entirety of the opening in the upper dielectric layer 110. Thus, for example, the sidewall thickness Ts may be substantially the same as the bottom thickness TB. In at least one embodiment, a thickness of the channel layer upper portions 106b may vary. In at least one embodiment, the sidewall thickness Ts may be less than the bottom thickness TB.

It should be noted that the adjacent transistor 200 in the second alternative configuration may have the same features as the features described above for the transistor 100. In particular, the channel layer upper portions 206b may have a carrier concentration greater than a carrier concentration of the channel layer lower portion 106a. The channel layer upper portions 206b in the adjacent transistor 200 may alternatively include a material different than the material the channel layer upper adjacent transistor 200 may alternatively include a carrier concentration different than a carrier concentration of the channel layer upper portions 106b in the transistor 100. In some embodiments, the various thickness dimensions of the channel layer upper portion 206b of the adjacent transistor 200 may be the same or different than the various thickness dimensions of the channel upper portion 106b of the transistor.

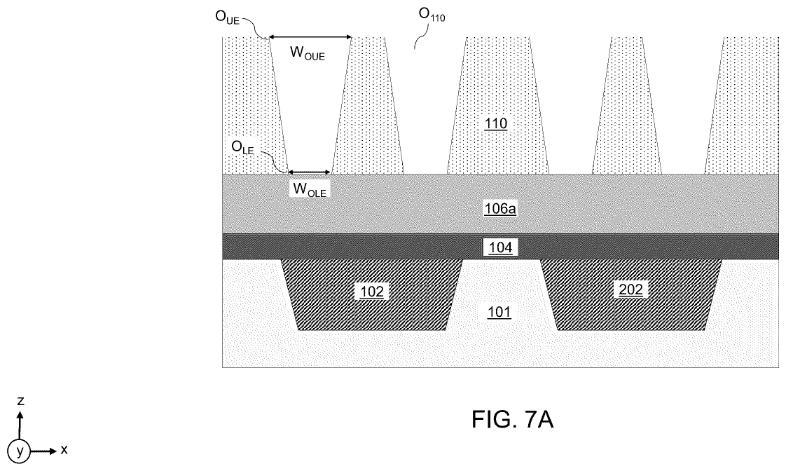

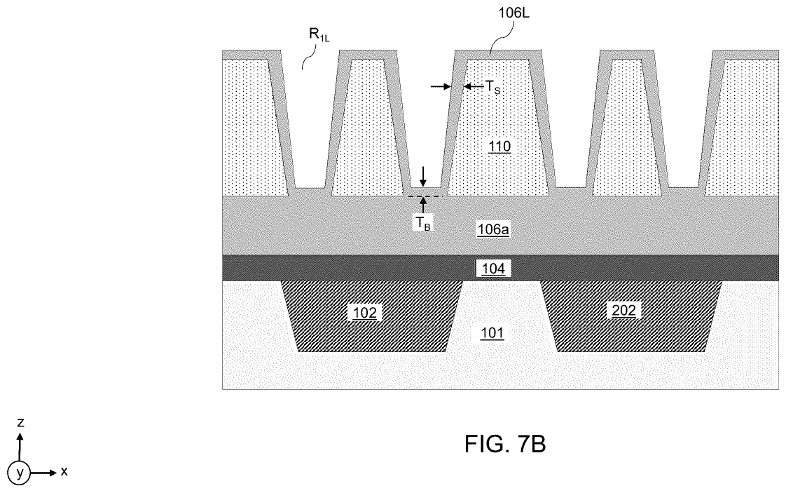

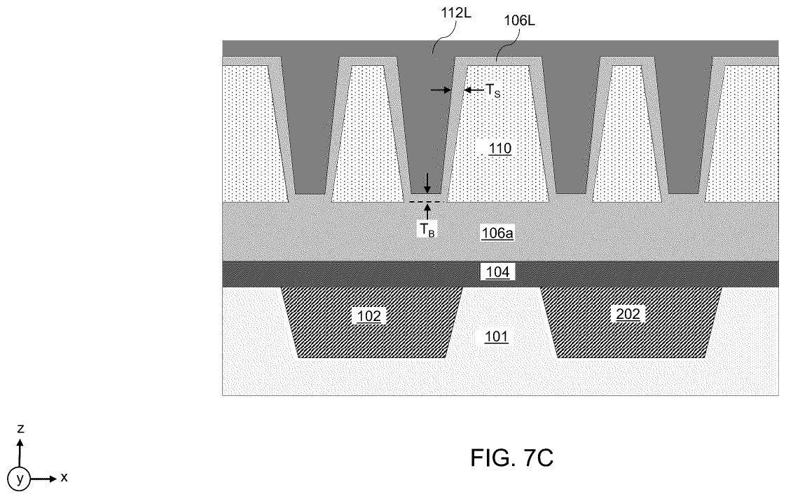

FIGS. 7A-7C are vertical cross-sectional views of various intermediate structures in a method of forming the semiconductor device 600 including the transistor 100 (e.g., a first transistor) and/or an adjacent transistor 200 (i.e., a second transistor) having the second alternative configuration. It should be noted that the adjacent transistor 200 may be formed concurrently with the forming of the transistor 100 using substantially the same processes as those used to form the transistor 100. However, in some embodiments in which the materials used in the transistor 100 differ from the materials used in adjacent transistor 200, the transistor 100 and adjacent transistor 200 may be formed in subsequent processes. For sake of simplicity, the process to form the transistor 100 and adjacent transistor 200 concurrently are illustrated and described. However, alternative methods in which subsequent process steps to form transistors of varying characteristics are within the contemplated scope of disclosure.

FIG. 7A is a vertical cross-sectional view of an intermediate structure including the openings O₁₁₀ in the upper dielectric layer 110 according to one or more embodiments. Starting with the intermediate structure illustrated in FIG. 2D, the upper dielectric layer 110 may be formed on the layer of channel material 106L, and then openings O₁₁₀ may be formed in the upper dielectric layer 110 in a manner similar to the manner described above with respect to FIG. 2G. In particular, a photolithographic process may be performed to pattern the upper dielectric layer 110 to include the openings O₁₁₀. The photolithographic process may include forming a patterned photoresist mask (not shown) on the upper dielectric layer 110, and etching (e.g., wet etching, dry etching, etc.) the upper dielectric layer 110 through openings in the photoresist mask to form the openings O₁₁₀.

The openings O₁₁₀ may be formed so as to penetrate an entire thickness of the upper dielectric layer 110. The openings O₁₁₀ may be formed so as to expose an upper surface of the channel layer lower portion 106a. The photoresist mask may be subsequently removed by ashing, dissolving the photoresist mask or by consuming the photoresist mask during the etch process.

The openings O₁₁₀ may also be formed to have an opening lower end OLE having a width WOLE in the first direction greater than 5 nm, and an opening upper end OUE having a width W_{OUE} in the first direction greater than 9 nm. The openings O₁₁₀ may be formed to have a substantially trapezoidal shape. Other shapes and sizes of the openings O₁₁₀ are within the contemplated scope of disclosure.

FIG. 7B is a vertical cross-sectional view of an intermediate structure including channel material 106L in the openings O₁₁₀ according to one or more embodiments. As illustrated in FIG. 7B, the channel material 106L may be conformally formed in the openings O₁₁₀. The channel material 106L may be formed in the openings O₁₁₀ so that a recess RIL is formed in the channel material 106L.

The channel material 106L may also be formed in the openings O₁₁₀ to have a sidewall thickness Ts greater than 0.5 nm on a sidewall of the openings O₁₁₀ and a bottom thickness TB greater than 0.5 nm on a bottom of the openings O₁₁₀. The channel material 106L may be deposited using a method other than PVD so that the channel material 106L may be conformally formed. Thus, for example, the channel material 106L may be deposited using, for example, by CVD, ALD, PECVD, LPCVD, or other suitable deposition method.

FIG. 7C is a vertical cross-sectional view of an intermediate structure including a metal material layer 112L on the channel material 106L according to one or more embodiments. After the channel material 106L are conformally formed in the openings O₁₁₀, a metal material layer 112L may be formed on the channel material 106L. In particular, the metal material layer 112L may be formed in the recesses RIL of the channel material 106L (see FIG. 7B). The metal material layer 112L may fill the recesses RIL of the channel material 106L (see FIG. 7B).

The metal material layer 112L may include, for example, one or more of TiN, TaN, W, Cu, Pt, Mo, Ru, Al, Ti, Ta, or other metal with low resistivity (e.g., less than 1×10⁻⁵ ohm-cm). Other materials for the metal material layer 112L are within the contemplated scope of disclosure. The metal material layer 112L may be deposited on the upper dielectric layer 110, for example, by CVD, PVD (e.g., sputtering), ALD, PECVD, LPCVD, or other suitable deposition method.

The metal material layer 112L and the channel material 106L may then be planarized by a planarizing process such as by CMP (not shown in FIG. 7C). The planarizing process may form the channel layer upper portions 106b in the openings O₁₁₀ and form the source/drain contacts 112 in the recesses R₁ of the channel layer upper portions 106b (see FIG. 6). The planarizing process may make an upper surface of the source/source contacts 112 substantially coplanar with an upper surface of the channel layer upper portions 106b and with an upper surface of the upper dielectric layer 110 (see FIG. 6).

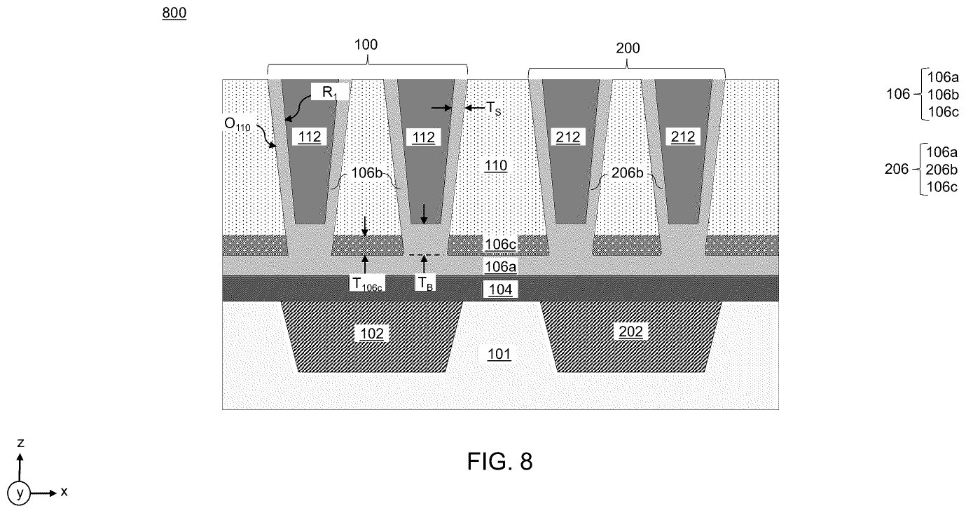

FIG. 8 is a vertical cross-sectional view of a semiconductor device 800 according to a third alternative embodiment. The semiconductor device 800 may include a transistor 100 (e.g., a first transistor) and/or an adjacent transistor 200 (i.e., a second transistor) having a third alternative configuration. It should be noted that the adjacent transistor 200 in the third alternative configuration may have the same features as the features described for the transistor 100. In some embodiments, the features of the adjacent transistor 200 in the third alternative configuration may be different features than the features described for the transistor 100.

As illustrated in FIG. 8, the transistor 100 having the third alternative configuration may be substantially similar to the transistor 100 having the second alternative configuration in FIG. 6. In particular, the channel layer upper portions 106b may be formed in openings O₁₁₀ in the upper dielectric layer 110 and the source/drain contacts 112 may be formed in recesses R₁ in the channel layer upper portions 106b. However, in the third alternative configuration, the channel layer 106 in the transistor 100 may include a channel layer intermediate portion 106c. At least a portion of the pair of channel layer upper portions 106b may be located in the channel layer intermediate portion 106c. The channel layer 206 in adjacent transistor 200 may also include the channel layer intermediate portion 106c.

The channel layer intermediate portion 106c may be formed on the channel layer lower portion 106a. The openings O₁₁₀ in the upper dielectric layer 110 may extend down into the channel layer intermediate portion 106c. The channel layer intermediate portion 106c may include one or more of IZO, ITO, In₂O₃, Ga₂O₃, InGaZnO, ZnO, Al₂O₅Zn₂, AZO, IWO, TiOₓ. The channel layer intermediate portion 106c may alternatively or additionally include semiconductor materials including other III-V materials, or combinations (e.g., alloys or stacked layers) of semiconductor materials. A material of the channel layer intermediate portion 106c may be the same or different than a material of the channel layer lower portion 106a and a material of the channel layer upper portions 106b.

As illustrated in FIG. 8, a bottom thickness TB of the channel layer upper portions 106b may be greater than a sidewall thickness Ts of the channel layer upper portions 106b. In at least one embodiment, the bottom thickness TB of the channel layer upper portions 106b may be at least twice the sidewall thickness Ts of the channel layer upper portions 106b. In at least one embodiment, the bottom thickness TB of the channel layer upper portions 106b may be greater than 1.0 nm. In at least one embodiment, the bottom thickness TB of the channel layer upper portions 106b may be greater than a thickness T_{106c} of the channel layer intermediate portion 106c.

In at least one embodiment, the channel layer lower portion 106a, channel layer upper portions 106b and channel layer intermediate portion 106c may include different carrier concentrations. In at least one embodiment, the channel layer intermediate portion 106c may have a first carrier concentration, and the channel layer lower portion 106a and channel layer upper portions 106b may include a second carrier concentration different than the first carrier concentration. In at least one embodiment, the second carrier concentration may be greater than the first carrier concentration.

In at least one embodiment, the second carrier concentration of the channel layer lower portion 106a and channel layer upper portions 106b may include a high carrier concentration and the first carrier concentration of the channel layer intermediate portion 106c may include a low carrier concentration. In at least one embodiment, the second carrier concentration of the channel layer lower portion 106a and channel layer upper portions 106b may be in a range from about 1×10¹⁸ cm⁻³ to 1×10²⁰ cm⁻³, and the first carrier concentration of the channel layer intermediate portion 106c may be in a range from about 5×10¹⁶ cm⁻³ to 1×10¹⁸ cm⁻³.

In at least one embodiment, the high carrier concentration of the channel layer lower portion 106a and channel layer upper portions 106b may provide the transistor 100 with a high ON current, and the low carrier concentration of the channel layer intermediate portion 106c may provide the transistor 100 with a high threshold voltage (Vt)). Thus, the transistor 100 having the third alternative configuration may have both high Vt and driving current. By integrating the bi-layer structure with a re-deposition of the channel material (e.g., the channel layer upper portions 106b are formed in the opening O₁₁₀ in the upper dielectric layer 110), the transistor 100 having the third alternative configuration may have a good threshold voltage/ON current (Vt/Ion) and negative bias stress (NBS) Vt stability at the same time.

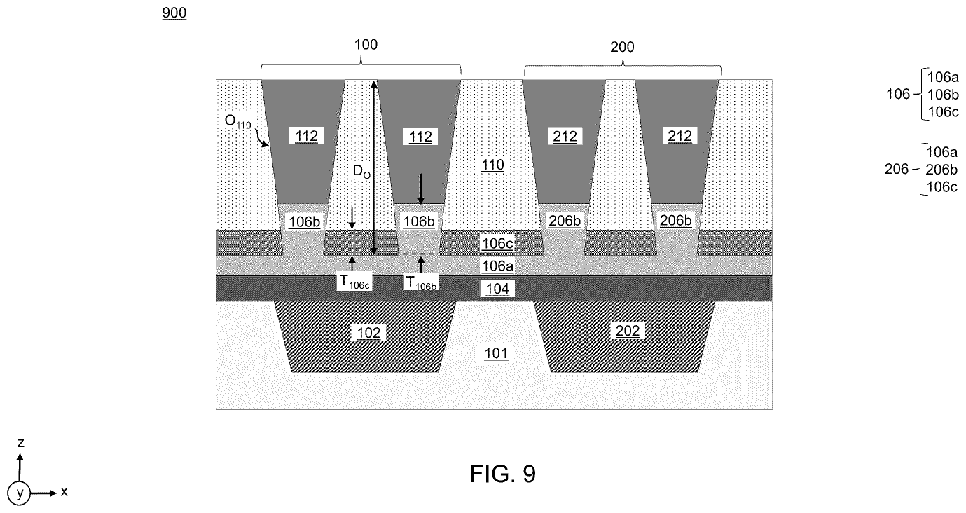

FIG. 9 is a vertical cross-sectional view of a semiconductor device 900 according to a fourth alternative embodiment. The semiconductor device 900 may include a transistor 100 (e.g., a first transistor) and/or an adjacent transistor 200 (i.e., a second transistor) having a fourth alternative configuration. It should be noted that the adjacent transistor 200 in the fourth alternative configuration may have the same features as the features described for the transistor 100. In some embodiments, the features of the adjacent transistor 200 in the fourth alternative configuration may be different than the features described for the transistor 100.

As illustrated in FIG. 9, the fourth alternative configuration of the transistor 100 may be substantially the same as the third alternative configuration in FIG. 8. However, in the fourth alternative configuration, the channel layer upper portions 106b may be located in a bottom of the openings O₁₁₀ but may not be conformally formed on a sidewall of the openings O₁₁₀.

The channel layer upper portions 106b may have a substantially flat upper surface in the openings O₁₁₀. The source/drain contacts 112 may be formed on the upper surface of the channel layer upper portions 106b in the openings O₁₁₀. The source/drain contacts 112 may fill the openings O₁₁₀ and have an upper surface substantially coplanar with an upper surface of the upper dielectric layer 110. With this design, the transistor 100 having the fourth alternative configuration may allow for more source/drain material (e.g., metal) to be filled into the openings O₁₁₀ which may further help to reduce contact resistance.

The channel layer upper portions 106b may have a thickness T_{106b} greater than a thickness T_{106c} of the channel layer intermediate portion 106c. In at least one embodiment, the thickness T_{106b} of the channel layer upper portions 106b may be at least twice the thickness T_{106c} of the channel layer intermediate portion 106c. In at least one embodiment, the thickness T_{106b} of the channel layer upper portions 106b may be at least 30% of the depth Do of the opening O₁₁₀ in the upper dielectric layer 110.

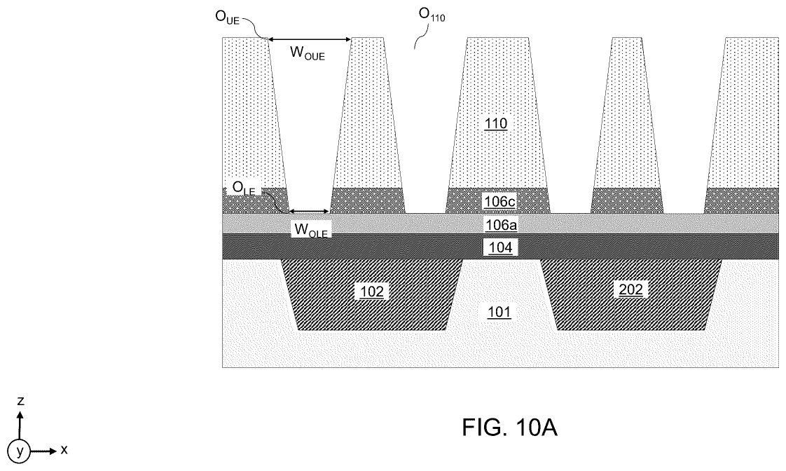

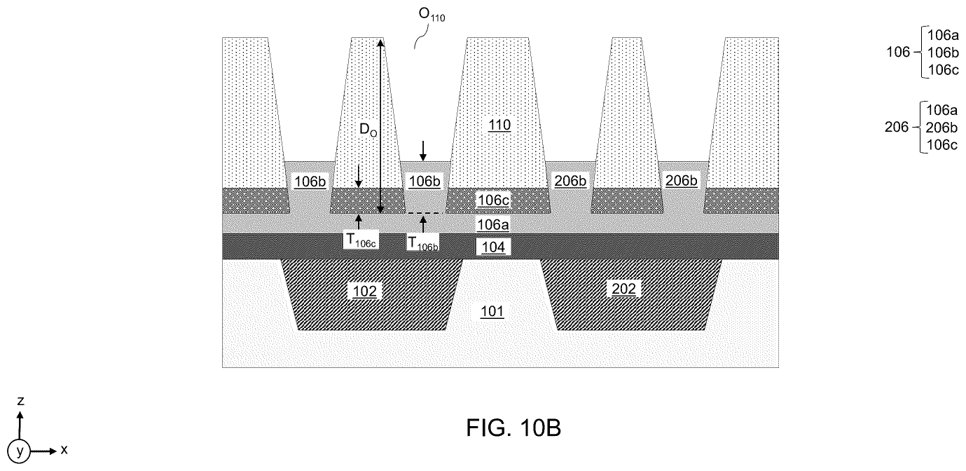

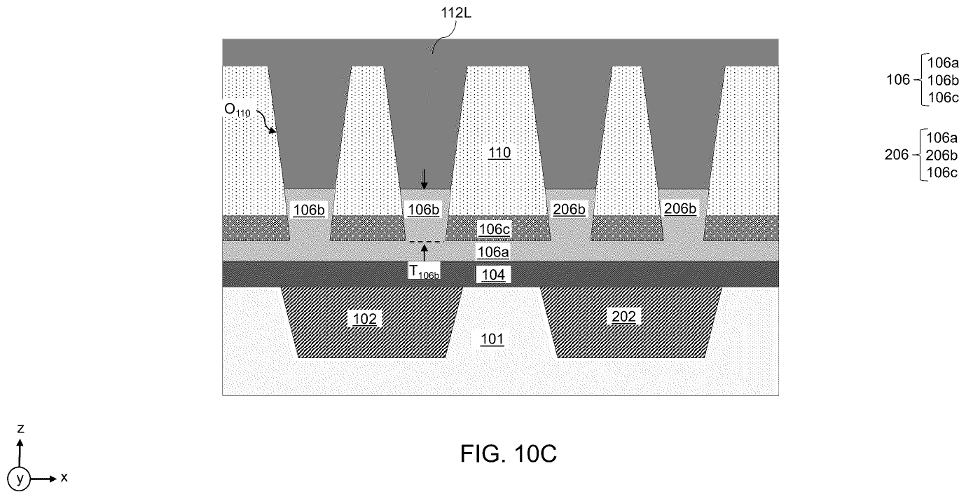

FIGS. 10A-10C are vertical cross-sectional views of various intermediate structures in a method of forming the transistor 100 (e.g., a first transistor) and/or an adjacent transistor 200 (i.e., a second transistor) having the fourth alternative configuration. It should be noted that the adjacent transistor 200 may be formed concurrently with the forming of the transistor 100 using substantially the same processes as those used to form the transistor 100. However, in some embodiments in which the materials used in the transistor 100 differ from the materials used in adjacent transistor 200, the transistor 100 and adjacent transistor 200 may be formed in subsequent processes. For sake of simplicity, the process to form the transistor 100 and adjacent transistor 200 concurrently are illustrated and described. However, alternative methods in which subsequent process steps to form transistors of varying characteristics are within the contemplated scope of disclosure.

FIG. 10A is a vertical cross-sectional view of an intermediate structure including the openings O₁₁₀ in the upper dielectric layer 110 according to one or more embodiments. The openings O₁₁₀ may be formed in the upper dielectric layer 110 in a manner similar to the manner described above with respect to FIG. 7A. In particular, a photolithographic process may be performed to pattern the upper dielectric layer 110 to include the openings O₁₁₀. The photolithographic process may include forming a patterned photoresist mask (not shown) on the upper dielectric layer 110, and etching (e.g., wet etching, dry etching, etc.) the upper dielectric layer 110 through openings in the photoresist mask to form the openings O₁₁₀.

The openings O₁₁₀ may be formed so as to penetrate an entire thickness of the upper dielectric layer 110. The openings O₁₁₀ may be formed so as to expose an upper surface of the channel layer lower portion 106a. The photoresist mask may be subsequently removed by ashing, dissolving the photoresist mask or by consuming the photoresist mask during the etch process.

The openings O₁₁₀ may also be formed to have an opening lower end OLE having a width WOLE in the first direction greater than 5 nm, and an opening upper end QUE having a width W_{OUE} in the first direction greater than 9 nm. The openings O₁₁₀ may be formed to have a substantially trapezoidal shape. Other shapes and sizes of the openings O₁₁₀ are within the contemplated scope of disclosure.

FIG. 10B is a vertical cross-sectional view of an intermediate structure including the channel layer upper portions 106b in the openings O₁₁₀ according to one or more embodiments. As illustrated in FIG. 10B, the channel layer upper portions 106b may be located at the bottom of the openings O₁₁₀ and may not be conformally formed on a sidewall of the openings O₁₁₀.

The channel layer upper portions 106b may be formed to have a thickness T_{106b} greater than a thickness T_{106c} of the channel layer intermediate portion 106c. In at least one embodiment, the channel layer upper portions 106b may be formed to have a thickness T_{106b} at least twice the thickness T_{106c} of the channel layer intermediate portion 106c. In at least one embodiment, the channel layer upper portions 106b may be formed to have the thickness T_{106b} at least 30% of the depth DO of the opening O₁₁₀ in the upper dielectric layer 110.

The channel layer upper portions 106b may be formed by a deposition process that deposits channel layer material in the bottom of the openings O₁₁₀, but does not conformally form channel layer material on a sidewall of the openings O₁₁₀. In at least one embodiment, a PVD process may be used to deposit the channel layer material in the opening O₁₁₀. Other suitable deposition methods are within the contemplated scope of disclosure.

FIG. 10C is a vertical cross-sectional view of an intermediate structure including a metal material layer 112L in the openings O₁₁₀ according to one or more embodiments. After the channel layer upper portions 106b are nonconformally formed at the bottom of the openings O₁₁₀, a metal material layer 112L may be formed on the channel layer upper portions 106b in the openings O₁₁₀. The metal material layer 112L may fill the openings O₁₁₀ in the upper dielectric layer 110.

The metal material layer 112L may include, for example, one or more of TiN, TaN, W, Cu, Pt, Mo, Ru, Al, Ti, Ta, or other metal with low resistivity (e.g., less than 1×10-5 ohm-cm). Other materials for the metal material layer 112L are within the contemplated scope of disclosure. The metal material layer 112L may be deposited on the upper dielectric layer 110, for example, by CVD, PVD (e.g., sputtering), ALD, PECVD, LPCVD, or other suitable deposition method.

The metal material layer 112L may then be planarized by a planarizing process such as by CMP (not shown in FIG. 10C, see FIG. 9). The planarizing process may form the source/drain contacts 112 in the openings O₁₁₀. The planarizing process may make an upper surface of the source/source contacts 112 substantially coplanar with an upper surface of the upper dielectric layer 110 (see FIG. 9).

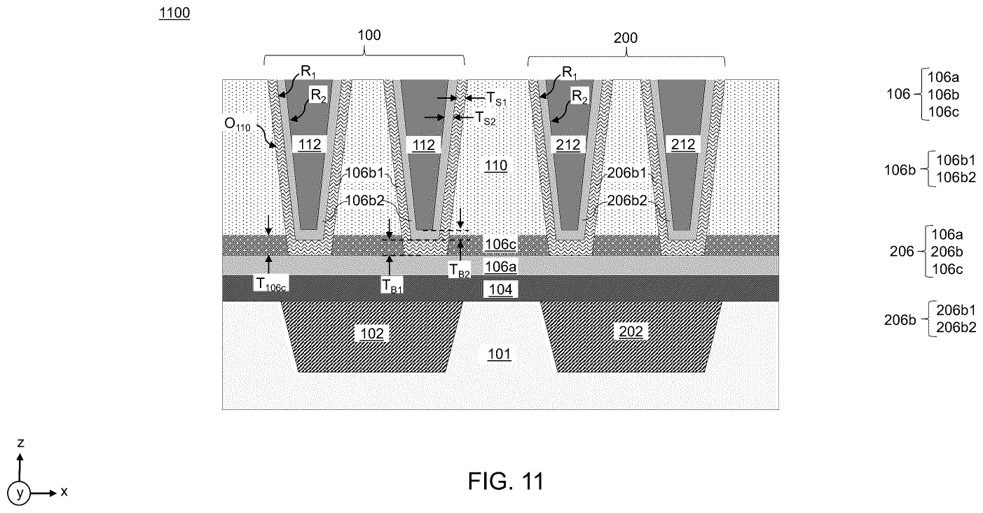

FIG. 11 is a vertical cross-sectional view of a semiconductor device 1100 according to a fifth alternative embodiment. The semiconductor device 1100 may include a transistor 100 (e.g., a first transistor) and/or an adjacent transistor 200 (i.e., a second transistor) having a fifth alternative configuration. It should be noted that the adjacent transistor 200 in the fifth alternative configuration may have the same features as the features described for the transistor 100. In some embodiments, the features of the adjacent transistor 200 in the fifth alternative configuration may be different than the features described for the transistor 100.

As illustrated in FIG. 11, the transistor 100 having the fifth alternative configuration may be substantially similar to the transistor 100 having the third alternative configuration in FIG. 8. In particular, the channel layer upper portions 106b may be formed in openings O₁₁₀ in the upper dielectric layer 110.

However, in the fifth alternative configuration of the transistor 100, the channel layer upper portions 106b may include first channel layer upper portions 106b1 formed in the openings O₁₁₀ in the upper dielectric layer 110, and second channel layer upper portions 106b2 formed in recesses R₁ in the first channel layer upper portions 106b1. The source/drain contacts 112 in the transistor 100 may be formed in recesses R₂ in the second channel layer upper portions 106b2. In the adjacent transistor 200, the channel layer upper portions 206b may include first channel layer upper portions 206b1 formed in the openings O₁₁₀ in the upper dielectric layer 110, and second channel layer upper portions 206b2 formed in recesses R₁ in the first channel layer upper portions 206b1. The source/drain contacts 212 in the adjacent transistor 200 may be formed in recesses R₂ in the second channel layer upper portions 206b2.

Thus, in the fifth alternative configuration of the transistor 100 in FIG. 11, multiple different channel layer materials may be used to form the channel layer upper portions 106b in the upper dielectric layer 110. By including multiple different channel layer materials in the channel layer 106, the fifth alternative configuration may help to obtain both high ON current and a reduction of the e-field.

Each of the channel layer lower portion 106a, the first channel layer upper portions 106b1, the second channel layer upper portions 106b2 and the channel layer intermediate portion 106c may include one or more of IZO, ITO, In₂O₃, Ga₂O₃, InGaZnO, ZnO, Al₂O₅Zn₂, AZO, IWO, TiOₓ. Each of the channel layer lower portion 106a, the first channel layer upper portions 106b1, the second channel layer upper portions 106b2 and the channel layer intermediate portion 106c may alternatively or additionally include semiconductor materials including other III-V materials, or combinations (e.g., alloys or stacked layers) of semiconductor materials.

Further, each of the channel layer lower portion 106a, the first channel layer upper portions 106b1, the second channel layer upper portions 106b2 and the channel layer intermediate portion 106c may include different materials. Thus, for example, the channel layer lower portion 106a may include a first channel layer material (e.g., IZO), the first channel layer upper portions 106b1 may include a second channel layer material (e.g., ITO), the second channel layer upper portions 106b2 may include a third channel layer material (e.g., AZO) and the channel layer intermediate portion 106c may include a fourth channel layer material (e.g., IWO). The channel layer lower portion 106a, first channel layer upper portions 106b1, second channel layer upper portions 106b2 and channel layer intermediate portion 106c may include the same or different carrier concentrations.

As further illustrated in FIG. 11, in the fifth alternative configuration of the transistor 100, the first channel layer upper portions 106b1 may have a bottom thickness T_{B1} and a sidewall thickness T_{S1} and the second channel layer upper portions 106b2 may have a bottom thickness T_{B2} and a sidewall thickness T_{S2}. The bottom thickness T_{B1} of the first channel layer upper portions 106b1 may be the same or different than the bottom thickness T_{B2} of the second channel layer upper portions 106b2. The sidewall thickness T_{S1} of the first channel layer upper portions 106b1 may be the same or different than the sidewall thickness T_{S2} of the second channel layer upper portions 106b2. Further, a combination thickness including the bottom thickness T_{B1} of the first channel layer upper portions 106b1 and the bottom thickness T_{B2} of the second channel layer upper portions 106b2 may be greater than, equal to or less than the thickness T_{106c} of the intermediate channel layer 106c.

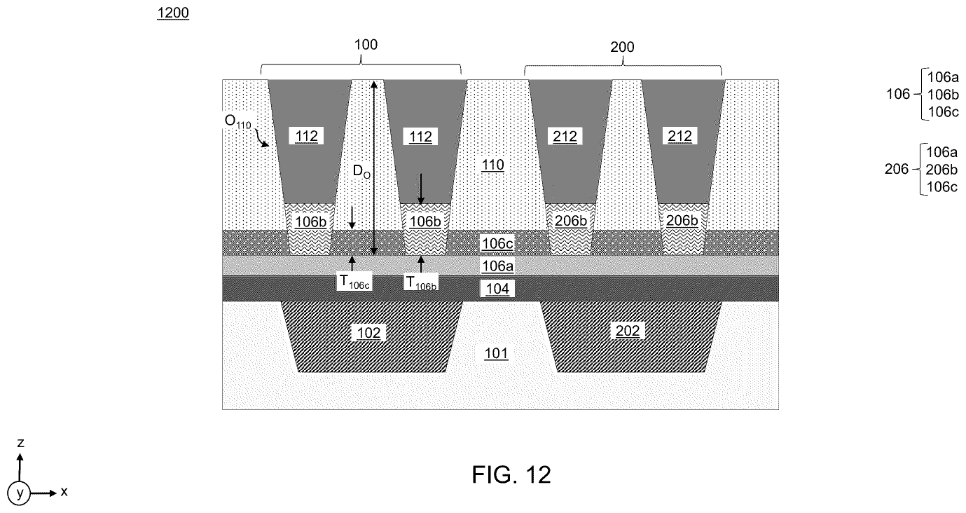

FIG. 12 is a vertical cross-sectional view of a semiconductor device 1200 according to a sixth alternative embodiment. The semiconductor device 1200 may include a transistor 100 (e.g., a first transistor) and/or an adjacent transistor 200 (i.e., a second transistor) having a sixth alternative configuration. It should be noted that the adjacent transistor 200 in the sixth alternative configuration may have the same features as the features described for the transistor 100. In some embodiments, the features of the adjacent transistor 200 in the sixth alternative configuration may be different than the features described for the transistor 100.

As illustrated in FIG. 12, the sixth alternative configuration of the transistor 100 may be substantially the same as the fourth alternative configuration in FIG. 9. In particular, the channel layer upper portions 106b may be located in a bottom of the openings O₁₁₀ but may not be conformally formed on a sidewall of the openings O₁₁₀. However, in the sixth alternative configuration, the channel layer lower portion 106a, the channel layer upper portions 106b and the channel layer intermediate portion 106c may include different channel layer materials. As with the fifth alternative configuration in FIG. 11, by including multiple different channel layer materials in the channel layer 106, the sixth alternative configuration illustrated in FIG. 12 may promote the obtaining of both high ON current and a reduction of the e-field.

In the sixth alternative configuration of the transistor 100 in FIG. 12, each of the channel layer lower portion 106a, the channel layer upper portions 106b and the channel layer intermediate portion 106c may include one or more of IZO, ITO, In₂O₃, Ga₂O₃, InGaZnO, ZnO, Al₂O₅Zn₂, AZO, IWO, TiOₓ. Each of the channel layer lower portion 106a, the channel layer upper portions 106b and the channel layer intermediate portion 106c may alternatively or additionally include semiconductor materials including other III-V materials, or combinations (e.g., alloys or stacked layers) of semiconductor materials.

Further, the channel layer lower portion 106a may include a first material, the channel layer upper portions 106b may include a second material different than the first material and the channel layer intermediate portion 106c may include a third material different than the first material and different than the second material. Thus, for example, the channel layer lower portion 106a may include a first channel layer material (e.g., IZO), the channel layer upper portions 106b may include a second channel layer material (e.g., ITO) and the channel layer intermediate portion 106c may include a third channel layer material (e.g., IWO). The carrier concentrations in the channel layer lower portion 106a, the channel layer upper portions 106b and channel layer intermediate portion 106c may be the same or different.

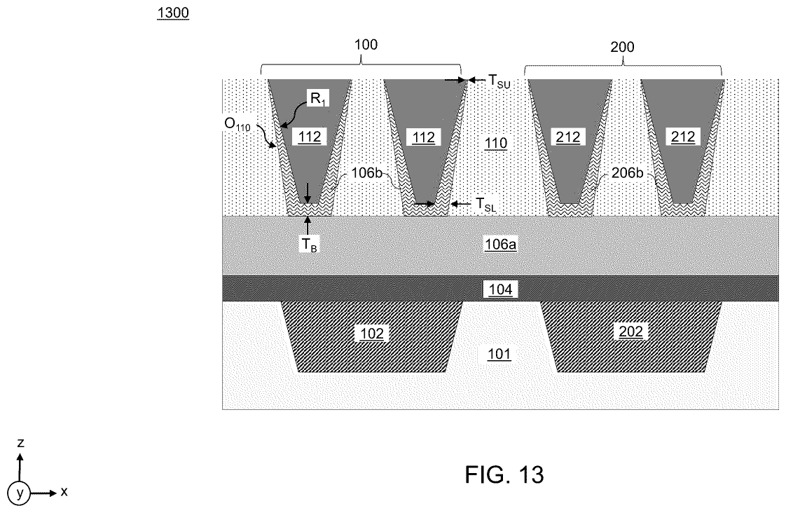

FIG. 13 is a vertical cross-sectional view of a semiconductor device 1300 according to a seventh alternative embodiment. The semiconductor device 1300 may include a transistor 100 (e.g., a first transistor) and/or an adjacent transistor 200 (i.e., a second transistor) having a seventh alternative configuration. It should be noted that the adjacent transistor 200 in the seventh alternative configuration may have the same features as the features described for the transistor 100. In some embodiments, the features of the adjacent transistor 200 in the seventh alternative configuration may be different than the features described for the transistor 100.

As illustrated in FIG. 13, the seventh alternative configuration of the transistor 100 may be substantially the same as the second alternative configuration in FIG. 6. In particular, the channel layer upper portions 106b may be formed in the opening O₁₁₀ of an upper dielectric layer 110, and the source/drain contacts 112 may be located in recesses R₁ in the channel layer upper portions 106b. However, in the seventh alternative configuration of the transistor 100 in FIG. 13, a thickness of the channel layer upper portions 106b may vary along a sidewall of the opening O₁₁₀. A material of the channel layer upper portions 106b may also be the same as or different than a material of the channel layer lower portion 106a.

In particular, as illustrated in FIG. 13, the channel layer upper portions 106b may have an upper sidewall thickness T_{SU} near the upper surface of the upper dielectric layer 110 and a lower sidewall thickness T_{SL} near the bottom of the recess R₁ different than the upper sidewall thickness T_{SU}. In at least one embodiment, the lower sidewall thickness T_{SL} may be greater than the upper sidewall thickness T_{SU}. In at least one embodiment, the thickness of the channel layer upper portions 106b may gradually increase from the upper sidewall thickness T_{SU} to the lower sidewall thickness T_{SL}. In at least one embodiment, the thickness of the channel layer upper portions 106b may increase linearly from the upper sidewall thickness T_{SU} to the lower sidewall thickness T_{SL}. In at least one embodiment, the upper sidewall thickness T_{SU} may be less than 10% of the lower sidewall thickness T_{SL}. In at least one embodiment, a width of the source/drain contacts 112 in the first direction (x-direction) at the upper surface of the upper dielectric layer 110 may be substantially equal to a width of the openings O₁₁₀ at the upper surface of the upper dielectric layer 110. The channel layer upper portions 106b may also include a bottom thickness TB which may be greater than less than or equal to the lower sidewall thickness T_{SL}.

In the seventh alternative configuration of the transistor 100 in FIG. 13, each of the channel layer lower portion 106a and the channel layer upper portions 106b may include one or more of IZO, ITO, In₂O₃, Ga₂O₃, InGaZnO, ZnO, Al₂O₅Zn₂, AZO, IWO, TiOₓ. Each of the channel layer lower portion 106a and the channel layer upper portions 106b may alternatively or additionally include semiconductor materials including other III-V materials, or combinations (e.g., alloys or stacked layers) of semiconductor materials.

Further, a material of the channel layer lower portion 106a may be different than a material of the channel layer upper portions 106b. Thus, for example, the channel layer lower portion 106a may include a first channel layer material (e.g., IZO) and the channel layer upper portions 106b may include a second channel layer material (e.g., ITO). The carrier concentrations in the channel layer lower portion 106a and channel layer upper portions 106b may be the same or different.

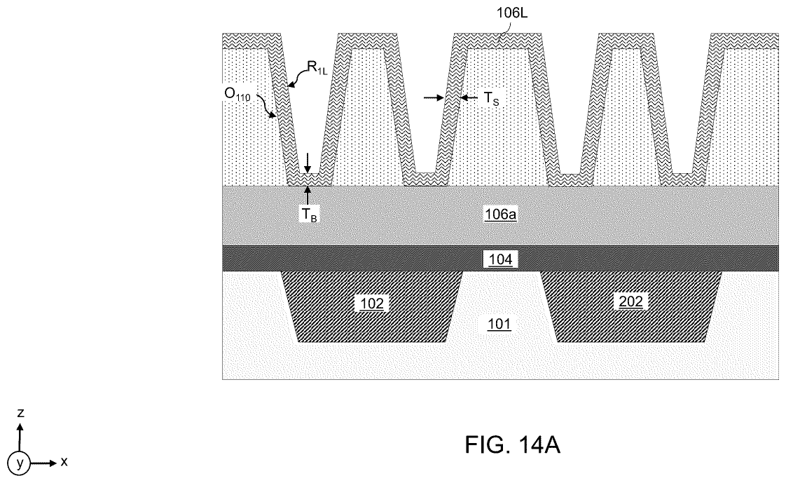

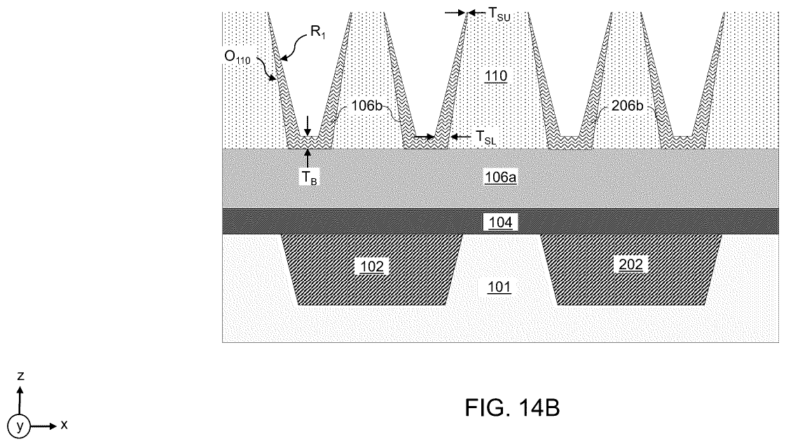

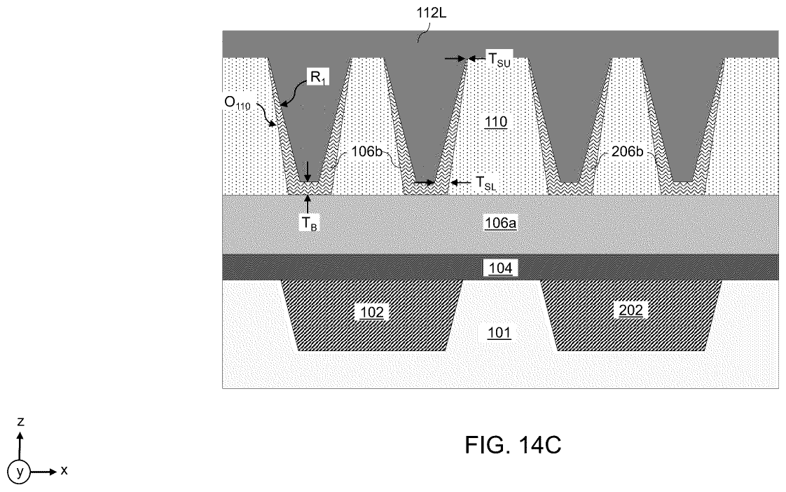

FIGS. 14A-14C are vertical cross-sectional views of various intermediate structures in a method of forming the semiconductor device 1300 including the transistor 100 (e.g., a first transistor) and/or an adjacent transistor 200 (i.e., a second transistor) having the seventh alternative configuration. The method of forming the transistor 100 having the seventh alternative configuration may be substantially similar to the method of forming the transistor 100 having the second alternative configuration in FIGS. 7A-7C. It should be noted that the adjacent transistor 200 may be formed concurrently with the forming of the transistor 100 using substantially the same processes as those used to form the transistor 100. However, in some embodiments in which the materials used in the transistor 100 differ from the materials used in adjacent transistor 200, the transistor 100 and adjacent transistor 200 may be formed in subsequent processes. For sake of simplicity, the process to form the transistor 100 and adjacent transistor 200 concurrently are illustrated and described. However, alternative methods in which subsequent process steps to form transistors of varying characteristics are within the contemplated scope of disclosure.

FIG. 14A is a vertical cross-sectional view of an intermediate structure including channel material 106L in the openings O₁₁₀ according to one or more embodiments. As illustrated in FIG. 14A, the channel material 106L may be conformally formed in the openings O₁₁₀. The channel material 106L may be formed in the openings O₁₁₀ so that a recess R_{1L} is formed in the channel material 106L.

The channel material 106L may also be formed in the openings O₁₁₀ to have a sidewall thickness Ts greater than 0.5 nm on a sidewall of the openings O₁₁₀ and a bottom thickness TB greater than 0.5 nm on a bottom of the openings O₁₁₀. The channel material 106L may be deposited using a method other than PVD so that the channel material 106L may be conformally formed. Thus, for example, the channel material 106L may be deposited using, for example, by CVD, ALD, PECVD, LPCVD, or other suitable deposition method.

FIG. 14B is a vertical cross-sectional view of an intermediate structure including the channel layer upper portions 106b according to one or more embodiments. After the channel material 106L is conformally formed in the openings O₁₁₀, an etching process may be performed to etch back a portion of the channel material 106L on the sidewall of the openings O₁₁₀. The etching process may be tailored to produce the varying thickness of the channel layer upper portions 106b on the sidewall of the openings O₁₁₀ while substantially maintaining a thickness TB of the channel layer upper portions 106b in the bottom of the recesses R₁. In particular, the etching process may be tailored to produce the upper sidewall thickness T_{SU} of the channel layer upper portions 106b near the upper surface of the upper dielectric layer 110 and the lower sidewall thickness T_{SL} of the channel layer upper portions 106b near the bottom of the recess R₁.

The etching process may include, for example, an anisotropic etching process such as reactive ion etching (RIE). In the etching process, parameters such as gas composition, pressure, and power may be controlled in order to achieve the varied thickness of the channel layer upper portions 106b on the sidewall of the openings O₁₁₀ while substantially maintaining a thickness TB of the channel layer upper portions 106b in the bottom of the recesses R₁.

FIG. 14C is a vertical cross-sectional view of an intermediate structure including a metal material layer 112L according to one or more embodiments. The metal material layer 112L may be formed on the channel layer upper portions 106b. In particular, the metal material layer 112L may be formed in the recesses R₁ of the channel layer upper portions 106b. The metal material layer 112L may fill the recesses R₁ of the channel layer upper portions 106b.

The metal material layer 112L may include, for example, one or more of TiN, TaN, W, Cu, Pt, Mo, Ru, Al, Ti, Ta, or other metal with low resistivity (e.g., less than 1×10⁻⁵ ohm-cm). Other materials for the metal material layer 112L are within the contemplated scope of disclosure. The metal material layer 112L may be deposited on the upper dielectric layer 110, for example, by CVD, PVD (e.g., sputtering), ALD, PECVD, LPCVD, or other suitable deposition method.

The metal material layer 112L and the upper dielectric layer 110 may then be planarized by a planarizing process such as by CMP. The planarizing process may form the source/drain contacts 112 in the recesses R₁ of the channel layer upper portions 106b (see FIG. 13). The planarizing process may make an upper surface of the source/source contacts 112 substantially coplanar with an upper surface of the channel layer upper portions 106b and with an upper surface of the upper dielectric layer 110 (see FIG. 13).

In FIGS. 5-14C, the transistor 100 and adjacent transistor 200 are illustrated as having the same characteristics in terms of types of transistors (e.g., p-type or n-type), materials used for each of the components (e.g., material for gate, channel layer upper portions and channel layer lower portions), and dimensions (e.g., thickness of channel layer upper portions, thickness of contacts, etc.). Embodiments are contemplated in which these various characteristics may be the same or different between the transistor 100 and adjacent transistor 200. For sake of simplicity, the description of the various permutations of differences and processes to form the varying permutation are omitted.

Referring to FIGS. 1A-14C, a transistor 100 may include a gate 102, a gate dielectric layer 104 on the gate 102, a channel layer 106 on the gate dielectric layer 104 and including a channel layer lower portion 106a and a pair of channel layer upper portions 106b on the channel layer lower portion 106a, and a pair of source/drain contacts 112 on the pair of channel layer upper portions 106b, respectively.

In one embodiment, the pair of channel layer upper portions 106b may be located above the gate 102. In one embodiment, the gate dielectric layer 104 may include a high-k dielectric layer. In one embodiment, the source/drain contact 112 of the pair of source/drain contacts 112 may include a lower end 112a contacting a channel layer upper portion 106b of the pair of channel layer upper portions 106b, and a width of the channel layer upper portion 106b in a first direction may be greater than a width of the lower end of the source/drain contact 112 in the first direction. In one embodiment, the width of the lower end of the source/drain contact 112 may be greater than 5 nm and the channel layer upper portion 106b extends in the first direction beyond the lower end 112a by more than 2 nm. In one embodiment, the gate 102 may extend in the first direction beyond the channel layer upper portion 106b by more than 2 nm. In one embodiment, each of a length of the channel layer upper portion 106b in a second direction perpendicular to the first direction and a length of the source/drain contact 112 in the second direction may be greater than 10 nm. In one embodiment, the pair of channel layer upper portions 106b may include a carrier concentration greater than a carrier concentration of the channel layer lower portion 106a. In one embodiment, the gate 102 may be in a lower dielectric layer 101, and the pair of source/drain contacts 112 may be in an upper dielectric layer 110 on the channel layer 106. In one embodiment, the pair of channel layer upper portions 106b may be in the upper dielectric layer 110, and the pair of source/drain contacts 112 may be on an upper surface of the pair of channel layer upper portions 106b, respectively. In one embodiment, a source/drain contact 112 of the pair of source/drain contacts 112 may be tapered in a direction toward the gate 102 and a channel layer upper portion 106b of the pair of channel layer upper portions 106b may be on a sidewall of the source/drain contact. In one embodiment, the channel layer lower portion 106a may include a first material and the pair of channel layer upper portions 106b may include a second material different than the first material. In one embodiment, the thickness of the pair of channel layer upper portions 106b may decrease in a direction away from the channel layer lower portion 106a. In one embodiment, the channel layer 106 may further include a channel layer intermediate portion on the channel layer lower portion 106a, and the pair of channel layer upper portions 106b may be in the channel layer intermediate portion. In one embodiment, the channel layer intermediate portion may include a carrier concentration less than a carrier concentration of the channel layer lower portion 106a. In one embodiment, the channel layer lower portion 106a may include a first material, the channel layer intermediate portion may include a second material different than the first material, and the pair of channel layer upper portions 106b may include a third material different than the first material and the second material.

Referring again to FIGS. 1A-14C, a method of forming a transistor 100 may include forming a gate dielectric layer 104 on a lower dielectric layer 101 including a gate 102, depositing a layer of channel material 106L on the gate dielectric layer 104, patterning the layer of channel material 106L to form a channel layer 106 including a channel layer lower portion 106a and a pair of channel layer upper portions 106b on the channel layer lower portion 106a, forming an upper dielectric layer 110 on the channel layer 106, and forming a pair of source/drain contacts 112 in the upper dielectric layer 110 on the pair of channel layer upper portions 106b, respectively.

In one embodiment method, the forming of the pair of source/drain contacts 112 may include forming a source/drain contact 112 of the pair of source/drain contacts 112 to include a lower end contacting a channel layer upper portion 106b of the pair of channel layer upper portions 106b, and a width of the channel layer upper portion 106b in a first direction may be greater than a width of the lower end of the source/drain contact 112 in the first direction. In one embodiment method, the depositing of the layer of channel material 106L may include depositing a first layer of channel material and depositing a second layer of channel material on the first layer of channel material, and the patterning of the layer of channel material may include patterning the second layer of channel material to form the pair of channel layer upper portions 106b.

Referring again to FIGS. 1A-14C, a semiconductor device 300, 400, 500, 600, 800, 900, 1100, 1200, 1300 may include a first transistor 100 including a first gate 102, a gate dielectric layer 104 on the first gate 102, a channel layer 106 on the gate dielectric layer 104 and including a channel layer lower portion 106a and a first pair of channel layer upper portions 106b on the channel layer lower portion 106a, and a first pair of source/drain contacts 112 on the first pair of channel layer upper portions 106b, respectively, and a second transistor 200 adjacent the first transistor 100, including a second gate 202 adjacent the first gate 102, wherein the gate dielectric layer 104 may be on the second gate 202, a second pair of channel layer upper portions 206b on the channel layer lower portion 106a, and a second pair of source/drain contacts 212 on the second pair of channel layer upper portions 206b, respectively.

According to an aspect of the various embodiments disclosed herein, a transistor 100 (and adjacent transistor 200) in the various embodiments (e.g., semiconductor devices 300, 400, 500, 600, 800, 900, 1100, 1200, 1300) may provide different approaches to stacking up a source/drain contact in a transistor 100 (e.g., TFT). The transistor 100 may utilize a channel layer upper portion 106b to stack up the source/drain contact 112, causing the formation of a low e-field region in the channel layer 106 and gate dielectric layer 104. The low e-field region may result in a lower threshold voltage (Vt) shift during bias stress and an improve time dependent breakdown behavior. The channel layer upper portion 106b may, therefore, provide the transistor 100 with an improved reliability. The transistor 100 may also utilize multiple different channel layer materials to help obtain both high ON current and a reduction of the e-field.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor, comprising:
a gate;
a gate dielectric layer on the gate;
a channel layer on the gate dielectric layer and including a channel layer lower portion and a pair of channel layer upper portions on the channel layer lower portion; and
a pair of source/drain contacts on the pair of channel layer upper portions, respectively.

2. The transistor of claim 1, wherein the pair of channel layer upper portions is located above the gate.

3. The transistor of claim 1, wherein the gate dielectric layer comprises a high-k dielectric layer.

4. The transistor of claim 1, wherein a source/drain contact of the pair of source/drain contacts comprises a lower end contacting a channel layer upper portion of the pair of channel layer upper portions, and a width of the channel layer upper portion in a first direction is greater than a width of the lower end of the source/drain contact in the first direction.

5. The transistor of claim 4, wherein the width of the lower end of the source/drain contact is greater than 5 nm and the channel layer upper portion extends in the first direction beyond the lower end by more than 2 nm.

6. The transistor of claim 5, wherein the gate extends in the first direction beyond the channel layer upper portion by more than 2 nm.

7. The transistor of claim 4, wherein each of a length of the channel layer upper portion in a second direction perpendicular to the first direction and a length of the source/drain contact in the second direction are greater than 10 nm.

8. The transistor of claim 1, wherein the pair of channel layer upper portions comprises a carrier concentration greater than a carrier concentration of the channel layer lower portion.

9. The transistor of claim 1, wherein the gate is in a lower dielectric layer, and the pair of source/drain contacts is in an upper dielectric layer on the channel layer.

10. The transistor of claim 9, wherein the pair of channel layer upper portions is in the upper dielectric layer, and the pair of source/drain contacts is on an upper surface of the pair of channel layer upper portions, respectively.

11. The transistor of claim 9, wherein a source/drain contact of the pair of source/drain contacts is tapered in a direction toward the gate and a channel layer upper portion of the pair of channel layer upper portions is on a sidewall of the source/drain contact.

12. The transistor of claim 11, wherein the channel layer lower portion comprises a first material and the pair of channel layer upper portions comprises a second material different than the first material.

13. The transistor of claim 11, wherein a thickness of the pair of channel layer upper portions decreases in a direction away from the channel layer lower portion.

14. The transistor of claim 11, wherein the channel layer further comprises a channel layer intermediate portion on the channel layer lower portion, and the pair of channel layer upper portions is in the channel layer intermediate portion.

15. The transistor of claim 14, wherein the channel layer intermediate portion comprises a carrier concentration less than a carrier concentration of the channel layer lower portion.

16. The transistor of claim 14, wherein the channel layer lower portion comprises a first material, the channel layer intermediate portion comprises a second material different than the first material, and the pair of channel layer upper portions comprises a third material different than the first material and the second material.

17. A method of forming a transistor, the method comprising:
forming a gate dielectric layer on a lower dielectric layer including a gate;
depositing a layer of channel material on the gate dielectric layer;
patterning the layer of channel material to form a channel layer including a channel layer lower portion and a pair of channel layer upper portions on the channel layer lower portion;
forming an upper dielectric layer on the channel layer; and
forming a pair of source/drain contacts in the upper dielectric layer on the pair of channel layer upper portions, respectively.

18. The method of claim 17, wherein the forming of the pair of source/drain contacts comprises forming a source/drain contact of the pair of source/drain contacts to include a lower end contacting a channel layer upper portion of the pair of channel layer upper portions, and a width of the channel layer upper portion in a first direction is greater than a width of the lower end of the source/drain contact in the first direction.

19. The method of claim 17, wherein the depositing of the layer of channel material comprises depositing a first layer of channel material and depositing a second layer of channel material on the first layer of channel material, and the patterning of the layer of channel material comprises patterning the second layer of channel material to form the pair of channel layer upper portions.

20. A semiconductor device, comprising:
a first transistor, comprising:
a first gate;
a gate dielectric layer on the first gate;
a channel layer on the gate dielectric layer and including a channel layer lower portion and a first pair of channel layer upper portions on the channel layer lower portion; and
a first pair of source/drain contacts on the first pair of channel layer upper portions, respectively; and
a second transistor adjacent the first transistor, comprising:
a second gate adjacent the first gate, wherein the gate dielectric layer is on the second gate;
a second pair of channel layer upper portions on the channel layer lower portion; and
a second pair of source/drain contacts on the second pair of channel layer upper portions, respectively.
